(19) United States
(12) Patent Application Publication
(10) Pub. No.: US 2026/0052820 A1
(43) Pub. Date: Feb. 19, 2026

(54) LIGHT EMITTING ELEMENT, DISPLAY DEVICE AND METHOD FOR MANUFACTURING THE SAME

(71) Applicant: Samsung Display Co., Ltd., Yongin-si (KR)

(72) Inventors: Moon Jung AN, Yongin-si (KR); Jin Seok PARK, Yongin-si (KR); Hoo Keun PARK, Yongin-si (KR)

(21) Appl. No.: 19/203,503

(22) Filed: May 9, 2025

(30) Foreign Application Priority Data
Aug. 19, 2024 (KR) 10-2024-0110530

(51) Int. Cl. H10H 29/49; H10H 29/80

(52) U.S. Cl. CPC H10H 29/49; H10H 29/8325

(57) ABSTRACT

A light emitting element includes: a semiconductor stack including a first semiconductor layer, an active layer, and a second semiconductor layer; a conductive layer on a first surface of the semiconductor stack; a protective layer on side surfaces of the conductive layer, a side surface of the semiconductor stack, and the first surface of the conductive layer, and spaced from a second surface facing the first surface of the semiconductor stack; a contact electrode on one surface of the semiconductor stack; a selective reflection layer on the side surfaces of the conductive layer, the side surface of the semiconductor stack, and the first surface of the conductive layer outside the protective layer, and including an opening overlapping the contact electrode, wherein the selective reflection layer includes M pairs of first and second layers (M is an integer greater than or equal to 2).

### CROSS-REFERENCE TO RELATED APPLICATION

The present application claims priority to and the benefit of Korean Patent Application No. 10-2024-0110530, filed on Aug. 19, 2024, in the Korean Intellectual Property Office, the entire disclosure of which is incorporated by reference herein.

### BACKGROUND

### 1. Field

The present disclosure relates to a light emitting element, a display device, and a method for manufacturing the same.

### 2. Description of the Related Art

As the information society develops, the demand for display devices for displaying images is increasing in various forms. The display device may be a flat panel display device such as a liquid crystal display, a field emission display, or a light emitting display.

The light-emitting display device may include an organic light-emitting display device including an organic light-emitting diode (OLED) element as a light-emitting element, and a micro light-emitting display device including a micro light-emitting diode element (hereinafter, referred to as a micro light-emitting element) as a light-emitting element. Because the micro light-emitting diode element is made of an inorganic material, it has a long lifespan due to less deterioration issues compared to an organic light-emitting diode (OLED) element.

### SUMMARY

Aspects and features of embodiments of the present disclosure are to provide a light-emitting element capable of separating the light-emitting element from the semiconductor substrate by low laser power, a display device using the light-emitting element, and a manufacturing method thereof.

However, the present disclosure is not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, light emitting element includes a semiconductor layer stack including a first semiconductor layer, an active layer, and a second semiconductor layer, a conductive layer on a first surface of the semiconductor layer stack, a protective layer on side surfaces of the conductive layer, a side surface of the semiconductor stack, and the first surface of the conductive layer, and spaced from a second surface facing the first surface of the semiconductor stack, a contact electrode on one surface of the semiconductor stack, a selective reflection layer on the side surfaces of the conductive layer, the side surface of the semiconductor stack, and the first surface of the conductive layer outside the protective layer, and including an opening overlapping the contact electrode, wherein the selective reflection layer includes M pairs of first and second layers (M is an integer greater than or equal to 2), wherein the first layer of each pair is closer to the semiconductor stack than the second layer, and wherein a length of the first layer in each pair is different from a length of the second layer.

According to one or more embodiments, lengths of the first layers in different pairs of the semiconductor stack are different.

According to one or more embodiments, lengths of the first layers in different pairs decrease as the distance from the light emitting element of the first layers in different pairs decrease.

According to one or more embodiments, wherein a refractive index of the first layer is lower than a refractive index of the second layer.

According to one or more embodiments, the semiconductor stack further includes a third semiconductor layer on the second semiconductor layer.

According to one or more embodiments, the semiconductor stack further includes light extraction patterns in a concave cross-sectional shape on a top surface of the semiconductor stack.

According to one or more embodiments, the protective layer covers a side surface of the active layer, and wherein a distance between the top surface of the semiconductor stack and the protective layer in a height direction of the light emitting element is greater than a maximum length of one of the light extraction patterns in the height direction of the light emitting element.

According to one or more embodiments, the protective layer and the first layer include silicon oxide, and wherein the second layer includes titanium oxide.

According to one or more embodiments, the contact electrode includes a first contact electrode connected to the conductive layer exposed without being covered by the protective layer, and a second contact electrode connected to the second semiconductor layer exposed without being covered by the protective layer and the selective reflection layer.

According to one or more embodiments, the second contact electrode is in a hole penetrating the conductive layer and a portion of the semiconductor stack.

According to one or more embodiments, the contact electrode is connected to the conductive layer that is exposed and not covered by the protective layer.

According to one or more embodiments of the present disclosure, a display device includes a substrate, a pixel electrode layer on the substrate, a light emitting element on the pixel electrode, wherein the light emitting element includes a semiconductor layer stack including a first semiconductor layer, an active layer, and a second semiconductor layer, a conductive layer on a first surface of the semiconductor layer stack, a protective layer on side surfaces of the conductive layer, a side surface of the semiconductor stack, and a first surface of the conductive layer, and spaced from a second surface opposing the first surface of the semiconductor stack, a contact electrode on one surface of the semiconductor stack and a selective reflection layer on the side surfaces of the conductive layer, the side surface of the semiconductor stack, and the first surface of the conductive layer outside the protective layer, and including an opening overlapping the contact electrode, wherein the selective reflection layer includes M (M is an integer greater than or equal to 2) pairs of first and second layers, wherein the first layer of each pair is closer to the semiconductor stack than the second layer, and wherein a length of the first layer in each pair is different from a length of the second layer.

According to one or more embodiments, wherein the pixel electrode layer includes a pixel electrode and a common electrode that is spaced from the pixel electrode, and wherein the contact electrode includes a first contact electrode connected to the conductive layer exposed without being covered by the protective layer, and a second contact electrode connected to the second semiconductor layer exposed without being covered by the protective layer and the selective reflection layer.

According to one or more embodiments, the display device further includes an organic film on a portion of the pixel electrode and the common electrode, a first connection electrode connecting the first contact electrode and the pixel electrode and a second connection electrode connecting the second contact electrode and the common electrode.

According to one or more embodiments, the pixel electrode layer includes a pixel electrode, wherein the contact electrode is connected to the conductive layer that is exposed and not covered by the protective layer, wherein the display device further includes a common electrode on a light emitting element.

According to one or more embodiments, the display device further includes an organic film on the pixel electrode, and a connection electrode connecting the contact electrode and the pixel electrode.

According to one or more embodiments of the present disclosure, a method of manufacturing a display device includes forming a second semiconductor material layer, an active material layer, a first semiconductor material layer, and a conductive material layer on a semiconductor substrate, etching the second semiconductor material layer, the active material layer, the first semiconductor material layer, and the conductive material layer to form light emitting elements, each of the light emitting elements including the second semiconductor layer, the active layer, the first semiconductor layer, and the conductive layer, forming a protective layer and a selective reflection layer surrounding each of the light emitting elements, forming a mask pattern on the protective layer and the selective reflection layer to pattern them to cover the light emitting elements, and dipping the light emitting elements surrounded by the mask pattern into an etching fluid, wherein the dipping is performed until the protective layer on side surfaces of the light emitting element is etched and separated from the semiconductor substrate.

According to one or more embodiments, wherein the dipping is stopped before the protective layer on a side surface of the light emitting element reaches a side of the active layer.

According to one or more embodiments, the method of manufacturing a display device further includes forming a mask pattern on the protective layer and forming a contact electrode and disposing the conductive layer on each of the light emitting elements to face a target substrate, the irradiating a laser to transfer the light emitting elements to the target substrate, and the separating the light emitting elements from the semiconductor substrate.

In the display device according to one or more embodiments and the manufacturing method thereof, the light emitting element may be separated from the semiconductor substrate by a low laser power, thereby facilitating the transfer of the light emitting element.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to one or more embodiments.

FIG. 2 is a layout diagram illustrating a display device according to one or more embodiments.

FIG. 3 is a block diagram illustrating a display device according to one embodiment.

FIG. 4 is an equivalent circuit diagram illustrating a sub-pixel according to one or more embodiments.

FIG. 5 is a layout diagram illustrating pixels in a display area according to one or more embodiments.

FIG. 6 is a cross-sectional view illustrating an example of a cross-section of a display panel corresponding to the lines I1-I1′ in FIG. 5.

FIG. 7 is a cross-sectional view illustrating an example of an area A1 of FIG. 6 in detail.

FIG. 8 is a cross-sectional view illustrating an example of an area B of FIG. 7 in detail.

FIG. 9 is a cross-sectional view illustrating another example of the area B of FIG. 7 in detail.

FIG. 10 is a cross-sectional view illustrating another example of the area A of FIG. 6 in detail.

FIG. 11 is a drawing (e.g., a cross-sectional view) illustrating an enlarged view of an area B1 of FIG. 10.

FIG. 12 is a drawing (e.g., a cross-sectional view) illustrating another example of the area B1 of FIG. 10.

FIG. 13 is a cross-sectional view illustrating another example of a cross-section of a display panel corresponding to the lines I1-I1′ of FIG. 5.

FIG. 14 is a cross-sectional view illustrating in detail an example of an area A1 of FIG. 13

FIG. 15 is a cross-sectional view illustrating another example of the area A1 of FIG. 13 in detail.

FIG. 16 is a cross-sectional view illustrating another example of the area A1 of FIG. 13 in detail.

FIG. 17 is a cross-sectional view illustrating another example of a cross-section of a display panel corresponding to the line I1-I1′ of FIG. 5.

FIG. 18 is a cross-sectional view illustrating an example of an area A2 of FIG. 17 in detail.

FIG. 19 is a layout diagram illustrating pixels of the display area according to one or more embodiments.

FIG. 20 is a cross-sectional view illustrating an example of the cross-section of the display panel corresponding to the line I2-I2′ of FIG. 19.

FIG. 21 is a cross-sectional view illustrating an example of an area A3 of FIG. 20 in detail.

FIG. 22 is a cross-sectional view illustrating another example of the area A3 of FIG. 20 in detail.

FIG. 23 is a flow chart illustrating a method for manufacturing a display device according to one or more embodiments.

FIGS. 24-29 and 31-36 are drawings to illustrate a method for manufacturing a display device according to one or more embodiments, and FIG. 30 is an image to illustrate a protective layer and a selective reflection layer according to the dipping time of FIG. 29.

FIG. 37 is an example view of a smart watch including a display device according to one or more embodiments.

FIGS. 38 and 39 are example views of a virtual reality (VR) device including a display device according to one or more embodiments.

FIG. 40 is an example view of a VR device including a display device according to one or more embodiments.

FIG. 41 is an example view illustrating a vehicle instrument cluster and center fascia including display devices according to one or more embodiments.

FIG. 42 is an example view of a transparent display device including a display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and/or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory, which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of ordinary skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

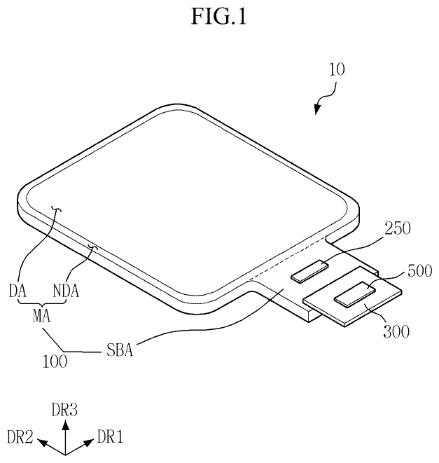

FIG. 1 is a perspective view illustrating a display device according to one or more embodiments.

Referring to FIG. 1, a display device 10 is a device for displaying video and/or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and ultra mobile PC (UMPC), as well as display screens for a variety of products such as televisions, laptops, monitors, billboards, and/or the internet of things (IOT).

The display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the present disclosure is not limited thereto. On the other hand, hereinafter, an ultra-small light emitting diode is described as a light emitting element for convenience of explanation.

The display device 10 includes a display panel 100, a display driving circuit 250, a circuit board 300, and a power supply circuit (or a power supply unit) 500.

The display panel 100 may be formed as a rectangular shaped plane having a short side in the first direction DR1 and a long side in the second direction DR2 that intersects the first direction DR1. A corner where the short side in the first direction DR1 and the long side in the second direction DR2 meet may be rounded to have a suitable curvature (e.g., a predetermined curvature) or may be formed at a right angle. The planar shape of the display panel 100 is not limited to a rectangle, but may be formed in other polygonal, circular, or oval shapes. The display panel 100 may be formed flat but is not limited thereto. In one example, the display panel 100 may be formed at the left and right ends and may include curved portions with a constant curvature or a changing curvature. In addition, the display panel 100 may be flexibly formed to be bent, curved, bent, folded, and/or rolled.

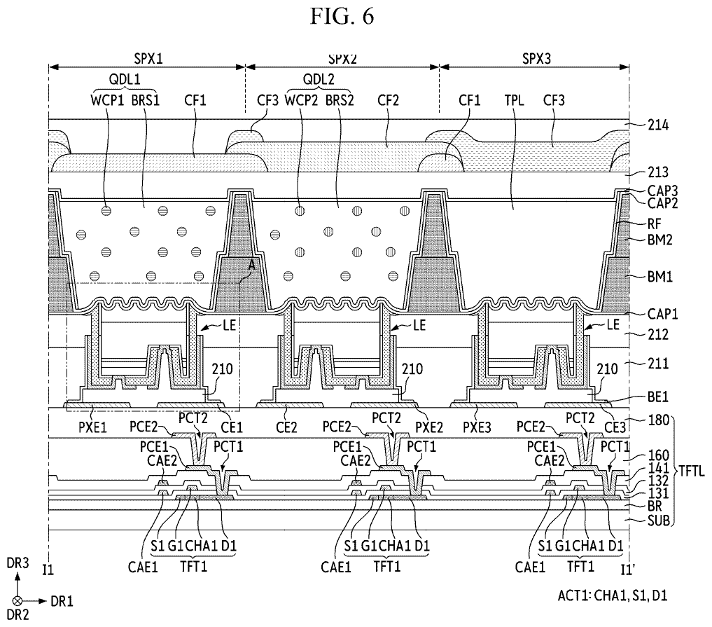

The substrate SUB (e.g., see FIG. 6) of the display panel 100 may include a main area MA and a sub area SBA.

The main area MA may include a display area DA that displays an image and a non-display area NDA that is a surrounding area of the display area DA. The display area DA may include a plurality of pixels that display an image. Each pixel may include a plurality of sub-pixels. For example, each of the pixels may include a first sub-pixel that emits light of a first color, a second sub-pixel that emits light of a second color, and a third sub-pixel that emits light of a third color. However, the present disclosure is not limited thereto.

The sub-area SBA may protrude from one side of the main area MA in the second direction DR2. Although FIG. 1 illustrates the sub-area SBA being unfolded, the sub-area SBA may be bent, and in this case, may be disposed on the lower surface of the display panel 100. When the sub-area SBA is bent, it may overlap the main area MA in the third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the display panel 100 using a chip on glass (COG) method, a chip on plastic (COP) method, and/or an ultrasonic bonding method but is not limited thereto. In one or more embodiments, the display driving circuit 250 may be attached to the circuit board 300 using a chip on film (COF) method.

The circuit board 300 may be attached to one end of the sub-area SBA of the display panel 100. As such, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible film, such as a flexible printed circuit board (FPCB), a printed circuit board (PCB), or a chip on film (CoF).

The power supply circuit 500 may generate a plurality of panel driving voltages according to an external power supply voltage. The power supply circuit 500 may be formed as an integrated circuit (IC) and attached to the circuit board 300 using a COF method.

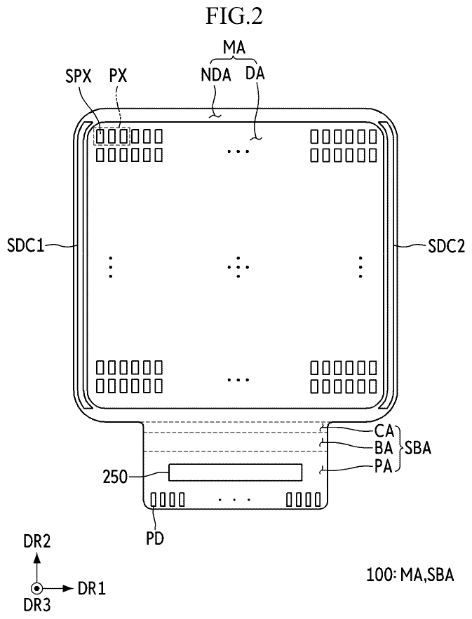

FIG. 2 is a layout drawing illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA includes a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be placed adjacent to the display area DA. The non-display area NDA may be an area outside the display area DA. The non-display area NDA may be arranged to be around (e.g., to surround) the display area DA. The non-display area NDA may be an edge area of the display panel 100.

A first scan driving portion SDC1 and a second scan driving portion SDC2 may be disposed in the non-display area NDA. The first scan driving portion SDC1 is disposed on one side (e.g., the left side) of the display panel 100, and the second scan driving portion SDC2 is disposed on the other side (e.g., the right side) of the display panel 100. However, the present disclosure is not limited thereto.

Each of the first scan driving portion SDC1 and the second scan driving portion SDC2 may be electrically connected to the display driving circuit 250 through scan fan out lines. Each of the first scan driving portion SDC1 and the second scan driving portion SDC2 may receive a scan control signal from the display driving circuit 250, generate scan signals according to the scan control signal, and output them to scan lines.

The sub-area SBA may protrude from one side of the main area MA in the second direction DR2. The length of the sub-area SBA in the second direction DR2 may be smaller than the length of the main area MA in the second direction DR2. The length of the sub area SBA in the first direction DR1 may be less than the length of the main area MA in the first direction DR1 or may be substantially equal to the length of the main area MA in the first direction DR1. The sub-area SBA may be curved and may be disposed at a lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are disposed. The display driving circuit 250 may be attached to the driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be disposed below the connection area CA and below the main area MA. The bending area BA may be disposed between the connection area CA and the pad area PA. One side of the bending area BA may be in contact with the connection area CA, and the other side of the bending area BA may be in contact with the pad area PA.

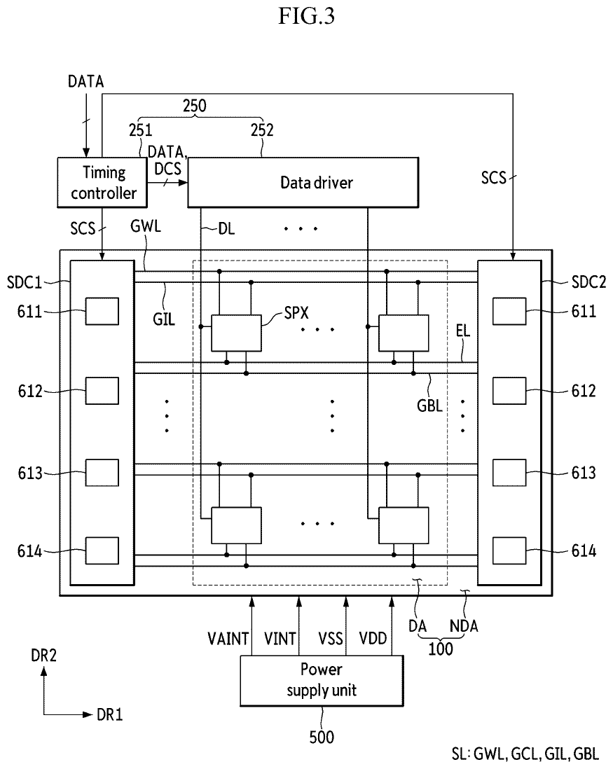

FIG. 3 is a block diagram illustrating a display device according to one or more embodiments.

Referring to FIG. 3, the display area DA includes a plurality of pixels PX, a plurality of scan lines SL, a plurality of emission control lines EL, and a plurality of data lines DL.

The plurality of pixels PX may be arranged in a matrix form along the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1 and may be arranged along the second direction DR2. The plurality of data lines DL may extend in the second direction DR2 and may be arranged along the first direction DR1. The plurality of scan lines SL may include a plurality of write scan lines GWL, a plurality of initialization scan lines GIL, and a plurality of bias scan lines GBL. In one or more embodiments, the plurality of scan lines SL may also include a plurality of control scan lines GCL.

Each of the plurality of sub-pixels SPX may be connected to a write scan line GWL from among the plurality of write scan lines GWL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. In one or more embodiments, each of the plurality of sub-pixels SPX may also be connected to a control scan line GCL from among the plurality of control scan lines GCL. Each of the plurality of sub-pixels SPX may be supplied with a data voltage of the data line DL according to the write scan signal of the write scan line GWL and may emit light from the light emitting elements according to the data voltage.

The non-display area NDA includes a first scan driving portion SDC1, a second scan driving unit SDC2, and a display driving circuit 250.

Each of the first scan driving portion SDC1 and the second scan driving portion SDC2 may include a write scan signal output portion 611, an initialization scan signal output portion 612, a bias scan signal output portion 613, and a light emitting signal output portion 614. In one or more embodiments, each of the first scan driving portion SDC1 and the second scan driving portion SDC2 may also include a control scan signal output portion. Each of the write scan signal output portion 611, the initialization scan signal output portion 612, the bias scan signal output portion 613, and the light emitting signal output portion 614 may receive a scan timing control signal SCS from the timing control circuit (or the timing controller) 251. The write scan signal output portion 611 may generate write scan signals according to the scan timing control signal SCS of the timing control circuit 251 and sequentially output them to the write scan lines GWL. The initialization scan signal output portion 612 may generate initialization scan signals according to the scan timing control signal SCS and sequentially output them to the initialization scan lines GIL. The bias scan signal output portion 613 may generate bias scan signals according to the scan timing control signal SCS and sequentially output them to the bias scan lines EBL. The light emitting signal output portion 614 may generate light emitting control signals according to the scan timing control signal SCS and sequentially output them to the emission control lines EL. In one or more embodiments, the control scan signal output portion may generate control scan signals according to the scan timing control signal SCS and sequentially output them to the control scan lines GCL.

The display driving circuit 250 includes the timing control circuit (or the timing controller) 251 and a data driving circuit (or a data driver) 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. In this case, the sub-pixels SPX are selected by the write scan signals of the first scan driving unit SDC1 and the second scan driving unit SDC2, and data voltages may be supplied to the selected sub-pixels SPX.

The timing control circuit 251 may receive digital video data DATA and timing signals from an external source. The timing control circuit 251 may generate the scan timing control signal SCS and the data timing control signal DCS to control the display panel 100 according to timing signals. The timing control circuit 251 may output the scan timing control signal SCS to the first scan driving unit SDC1 and the second scan driving unit SDC2. The timing control circuit 251 may output digital video data DATA and a data timing control signal DCS to the data driving circuit 252.

The power supply circuit (or the power supply unit) 500 may generate a plurality of panel driving voltages according to an external power supply voltage. For example, the power supply circuit 500 may generate and supply a first power supply voltage VDD, a second power supply voltage VSS, and a third power supply voltage VINT, and a fourth power supply voltage VAINT to the display panel 100.

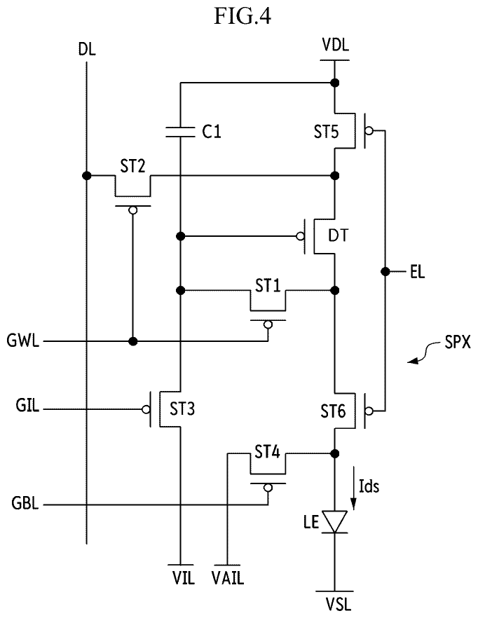

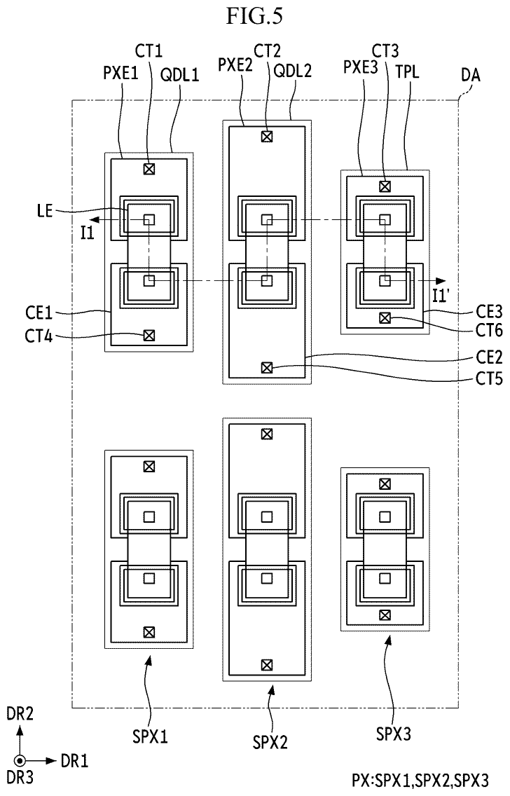

FIG. 4 is an equivalent circuit drawing illustrating a sub-pixel according to one or more embodiments.

Referring to FIG. 4, the sub-pixel SPX according to one or more embodiments may be connected to scan lines GWL, GIL, and GBL, an emission line EL, and a data line DL. For example, the sub-pixel SPX may be connected to the write scan line GWL, the initialization scan line GIL, the bias scan line GBL, the emission line EL, and the data line DL.

The sub-pixel SPX according to one or more embodiments includes a driving transistor DT, switch elements, a capacitor C1, and a light emitting element LE. The switch elements include first to sixth transistors ST1, ST2, ST3, ST4, ST5, and ST6. The driving transistor DT, switch elements, and capacitor C1 may be referred to as a pixel circuit PXC.

The driving transistor DT includes a gate electrode, a first electrode, and a second electrode. The driving transistor DT controls the drain-source current (Ids, hereinafter referred to as “driving current”) flowing between the first electrode and the second electrode of the driving transistor DT according to the data voltage applied to the gate electrode thereof.

The light emitting element LE may be a micro light emitting diode.

The light emitting element LE emits light according to the driving current Ids. The amount of light emitted from the light emitting element LE may be proportional to the driving current Ids. The anode electrode of the light emitting element LE is connected to the first electrode of the fourth transistor ST4 and the second electrode of the sixth transistor ST6, and the cathode electrode may be connected to a second power supply line VSL to which the second power voltage VSS is applied.

The capacitor C1 is formed between the gate electrode of the driving transistor DT and the first power supply line VDL to which the first power supply voltage VDD is applied. The first power supply voltage VDD may be at a higher level than the second power supply voltage VSS. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type metal-oxide-semiconductor field-effect transistors (MOSFETs). In this case, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, the gate electrode of the third transistor ST3 may be connected to the initialization scan line GIL, the gate electrode of the fourth transistor ST4 may be connected to the bias scan line GBL, and the gate electrodes of the fifth and sixth transistors may be connected to the emission line EL. Because the first to sixth transistors ST1, ST2, ST3, ST4, ST5, and ST6 are formed as p-type MOSFETs, they may be turned on when a scan signal and an emission signal with a gate low voltage are applied to the initialization scan line GIL, the write scan line GWL, the bias scan line GBL, and the emission line EL, respectively. One electrode of the third transistor ST3 and one electrode of the fourth transistor ST4 may be connected to the initialization voltage lines VIL and VAIL.

Alternatively, the driving transistor DT, the second transistor ST2, the fourth transistor ST4, the fifth transistor ST5, and the sixth transistor ST6 may be formed of a p-type MOSFETs, and the first transistor ST1 and the third transistor ST3 may be formed of an n-type MOSFETs. The active layers of each of the driving transistor DT, the second transistor ST2, the fourth transistor ST4, the fifth transistor ST5, and the sixth transistor ST6 formed of p-type MOSFETs are formed of polysilicon, and the active layers of each of the first transistor ST1 and the third transistor ST3 formed of an n-type MOSFET may be formed of an oxide semiconductor.

In this case, because the first transistor ST1 and the third transistor ST3 are formed as n-type MOSFETs, the first transistor ST1 may be turned on when a scan signal of the gate high voltage is applied, and the third transistor ST3 may be turned on when an initialization scan signal of the gate high voltage is applied. In contrast, the second transistor ST2, the fourth transistor ST4, the fifth transistor ST5, and the sixth transistor ST6 are formed as p-type MOSFETs, so they may be turned on when a scan signal of the gate low voltage and a light emission signal of the gate low voltage are applied.

Alternatively, the fourth transistor ST4 may be formed of an n-type MOSFET, so that the active layer of the fourth transistor ST4 may be formed of an oxide semiconductor. When the fourth transistor ST4 is formed of an n-type MOSFET, it may be turned on when a scan signal of the gate high voltage is applied.

Alternatively, the first to sixth transistors ST1, ST2, ST3, ST4, ST5, and ST6 and the driving transistor DT may all be formed as n-type MOSFETs. In this case, the active layer of each of the first to sixth transistors ST1, ST2, ST3, ST4, ST5, and ST6 and the driving transistor DT may be formed of an oxide semiconductor.

FIG. 5 is a layout diagram illustrating pixels in a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels, the sub-pixels may be the first sub-pixel SPX1, the second sub-pixel SPX2, and the third sub-pixel SPX3.

The plurality of pixels PX may be arranged in a matrix form. In each of the plurality of pixels PX, the first sub-pixel SPX1, the second sub-pixel SPX2, and the third sub-pixel SPX3 may be arranged along the first direction DR1.

When each of the plurality of pixels PX includes three sub-pixels SPX1, SPX2, and SPX3, the first sub-pixel SPX1 may emit light of a first color, and the second sub-pixel SPX2 may emit light of a second color, and the third sub-pixel SPX3 may emit light of a third color. Here, the first color light may be light in a red wavelength band, the second color light may be light in a green wavelength band, and the third color light may be light in a blue wavelength band. For example, the blue wavelength band may refer to light having a main peak wavelength in the wavelength band from approximately 370 nm to 460 nm, the green wavelength band may refer to light having a main peak wavelength in the wavelength band from approximately 480 nm to 560 nm, and the red wavelength band may refer to light having a main peak wavelength in the wavelength band from approximately 600 nm to 750 nm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1, a first common electrode CE1, a plurality of light emitting elements LE, and a first light conversion layer QDL1. The second sub-pixel SPX2 includes a second pixel electrode PXE2, a second common electrode CE2, a plurality of light emitting elements LE, and a second light conversion layer QDL2. The third sub-pixel SPX3 includes a third pixel electrode PXE3, a third common electrode CE3, a plurality of light emitting elements LE, and a light transmission layer TPL.

Each of the first pixel electrode PXE1, the second pixel electrode PXE2, and the third pixel electrode PXE3 may have a rectangular planar shape having a short side in the first direction DR1 and a long side in the second direction DR2. The area of the first sub-pixel SPX1, the area of the second sub-pixel SPX2, and the area of the third sub-pixel SPX3 may be set according to the light conversion efficiency of the first light conversion layer QDL1 and the light conversion efficiency of the second light conversion layer QDL2. That is, the area of the sub-pixel may become larger as the light conversion efficiency decreases.

For example, as shown in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1, and the area of the first pixel electrode PXE1 may be larger than the area of the third pixel electrode PXE3.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the first electrode of the fourth transistor (ST4 in FIG. 4) and the second electrode of the sixth transistor (ST6 in FIG. 4) of the corresponding sub-pixel.

Each of the pixel electrodes PXE1, PXE2, and PXE3 and the common electrodes CE1, CE2, and CE3 may have a rectangular planar shape. The area of the first pixel electrode PXE1 may be the same as the area of the first common electrode CE1, the area of the second pixel electrode PXE2 may be the same as the area of the second common electrode CE2, and the area of the third pixel electrode PXE3 may be the same as the area of the third common electrode CE3 but the present disclosure is not limited thereto.

In the first sub-pixel SPX1, the first pixel electrode PXE1 and the first common electrode CE1 may be disposed to be spaced (e.g., spaced apart) from each other in the second direction DR2. In the second sub-pixel SPX2, the second pixel electrode PXE2 and the second common electrode CE2 may be disposed to be spaced (e.g., spaced apart) from each other in the second direction DR2. In the third sub-pixel SPX3, the third pixel electrode PXE3 and the third common electrode CE3 may be disposed to be spaced (e.g., spaced apart) from each other in the second direction DR2.

The first common electrode CE1 may be connected to a second power supply line (VSL in FIG. 4) to which the second power supply voltage (VSS in FIG. 3) is applied through a first common connection hole (CT4). The second common electrode CE2 may be connected to the second power supply line VSL through a second common connection hole CT5. The third common electrode CE3 may be connected to a second power supply line VSL through a third common connection hole CT6. Therefore, the second power supply voltage VSS may be applied to each of the common electrodes CE1, CE2, and CE3.

A plurality of light emitting elements LE may be disposed on each of the pixel electrodes PXE1, PXE2, and PXE3 and the common electrodes CE1, CE2, and CE3. At least a portion of the pixel electrodes PXE1, PXE2, and PXE3 and the common electrodes CE1, CE2, and CE3 may be exposed without being covered by the light emitting elements LE. The same number of light emitting elements LE may be disposed on each of the pixel electrodes PXE1, PXE2, and PXE3. The plurality of light emitting elements LE may emit light of a third color, that is, light in a blue wavelength band, but the present disclosure is not limited thereto. When the light emitting element LE of the first sub-pixel SPX1 emits light of a first color, the light emitting element LE of the second sub-pixel SPX2 emits light of a second color, and the light emitting element LE of the third sub-pixel SPX3 emits light of a third color, the light conversion layers QDL1 and QDL2 and the light transmission layer TPL may be omitted.

The first light conversion layer QDL1 may completely overlap the first pixel electrode PXE1, the first common electrode CE1, and the plurality of light emitting elements LE of the first sub-pixel SPX1. The first light conversion layer QDL1 may convert or shift the peak wavelength of incident light into light of another specific peak wavelength and emit it. For example, the first light conversion layer QDL1 may convert or shift the third light emitted from the plurality of light emitting elements LE of the first sub-pixel SPX1 into the first light.

The second light conversion layer QDL2 may completely overlap with the second pixel electrode PXE2, the second common electrode CE2, and the plurality of light emitting elements LE of the second sub-pixel SPX2. The second light conversion layer QDL2 may convert or shift the peak wavelength of incident light into light of another specific peak wavelength and emit it. For example, the second light conversion layer QDL2 may convert or shift the third light emitted from the plurality of light emitting elements LE of the second sub-pixel SPX2 into the second light.

The light transmission layer TPL may completely overlap with the third pixel electrode PXE3, the third common electrode CE3, and the plurality of light emitting elements LE of the third sub-pixel SPX3. The light transmission layer TPL may directly transmit the incident light. For example, the light transmission layer TPL may directly transmit the third light emitted from the plurality of light emitting elements LE of the third sub-pixel SPX3.

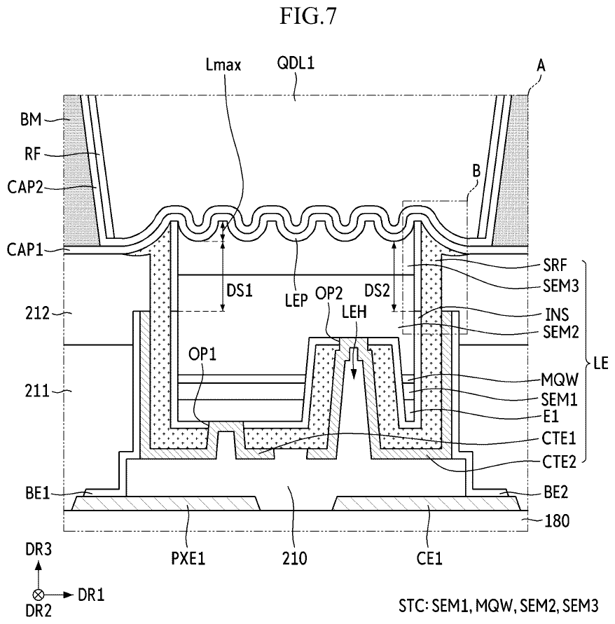

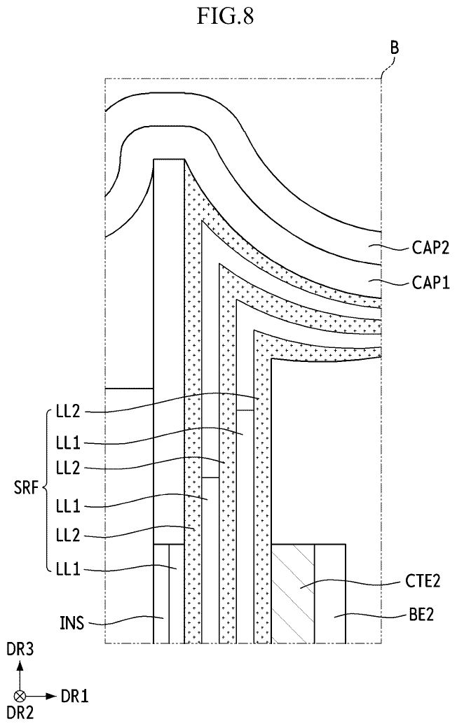

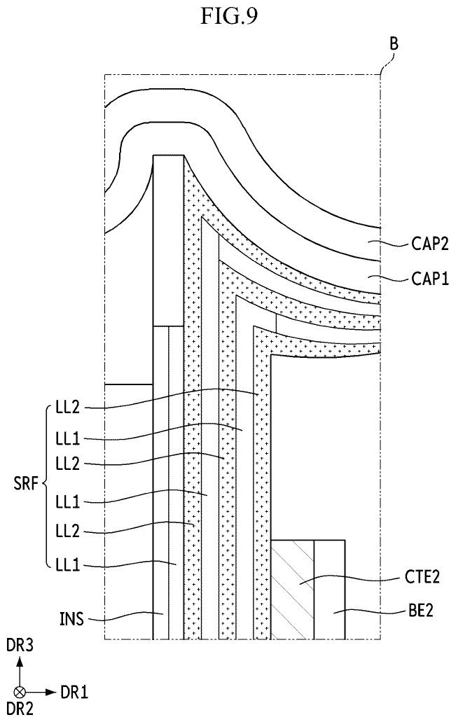

FIG. 6 is a cross-sectional view illustrating an example of a cross-section of a display panel corresponding to the lines I1-I1′ in FIG. 5. FIG. 7 is a cross-sectional view illustrating an example of an area A of FIG. 6 in detail. FIG. 8 is a cross-sectional view illustrating an example of an area B of FIG. 7 in detail. FIG. 9 is a cross-sectional view illustrating another example of the area B of FIG. 7 in detail.

Referring to FIGS. 6-7, a substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be disposed on the substrate SUB. The barrier film BR is a film that protects the transistors of the thin film transistor layer TFTL and the light emitting layer of the light emitting element layer from moisture penetrating through the substrate SUB which is vulnerable to moisture permeation. The barrier film BR may be composed of a plurality of inorganic films stacked alternately.

A thin film transistor TFT1 may be disposed on the barrier film BR. The thin film transistor TFT1 may be either the fourth transistor ST4 or the sixth transistor ST6 shown in FIG. 4. The thin film transistor TFTL may include a first active layer ACT1 and a first gate electrode G1.

The first active layer ACT1 of the thin film transistor TFT1 may be disposed on the barrier film BR. The first active layer ACT1 of the thin film transistor TFT1 may include polycrystalline silicon, monocrystalline silicon, low-temperature polycrystalline silicon, and/or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), and/or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be disposed on the first channel area CHA1, the first source area S1, and the first drain area D1 of the thin film transistor TFT1 and on the barrier film BR.

A first gate metal layer may be disposed on the first gate insulating film 131. The first gate metal layer may include a first gate electrode G1 of a thin film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being spaced (e.g., spaced apart) from each other in FIG. 6, the first gate electrode G1 and the first capacitor electrode CAE1 may be connected to each other.

A second gate insulating film 132 may be disposed on the first gate electrode G1 and the first capacitor electrode CAE1 of the thin film transistor TFT1 and on the first gate insulating film 131.

A second gate metal layer may be disposed on the second gate insulating film 132. The second gate metal layer may include a second capacitor electrode CAE2. The second capacitor electrode CAE2 may overlap the first capacitor electrode CAE1 of the thin film transistor TFT1 in the third direction DR3. Because the second gate insulating film 132 has a suitable dielectric constant (e.g., a predetermined dielectric constant), the capacitor (C1 in FIG. 4) may be formed by the first capacitor electrode CAE1, the second capacitor electrode CAE2, and the second gate insulating film 132 disposed between them.

A first interlayer insulating film 141 may be disposed on the second capacitor electrode CAE2 and the second gate insulating film 132.

A first data metal layer may be disposed on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the interlayer insulating film 141.

A first planarization organic film 160 may be disposed on the first source connection electrode PCE1 and the first interlayer insulating film 141 to planarize a step caused by the thin film transistor TFT1.

A second data metal layer may be disposed on the first planarization organic film 160. The second data metal layer may include a second source connection electrode PCE2. The second source connection electrode PCE2 may be connected to the first source connection electrode PCE1 through a second pixel contact hole (PCT2) penetrating the first planarization organic film 160.

A second planarization organic film 180 may be disposed on the second source connection electrode PCE2 and on the first planarization organic film 160.

The barrier film BR, the first gate insulating film 131, the second gate insulating film 132, the interlayer insulating film 141 may be formed of an inorganic film, for example, silicon nitride (SiNₓ), silicon oxide (SiON), silicon oxide (SiOₓ), titanium oxide (TiOₓ), or aluminum oxide (AlOₓ).

The first gate metal layer, the second gate metal layer, the first data metal layer, and the second data metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

The first planarization organic film 160 and the second planarization organic film 180 may be formed of an organic film such as an acrylic resin, an epoxy resin, a phenolic resin, a polyamide resin, a polyimide resin, and/or the like.

A light emitting element layer may be disposed on the second planarization organic film 180. The light emitting element layer may include, at least, the pixel electrodes PXE1, PXE2, PXE3, light emitting elements LE, the common electrodes CE1, CE2, CE3, and a first organic layer 210.

A pixel electrode layer may be disposed on the second planarization organic film 180. The pixel electrode layer may include the pixel electrodes PXE1, PXE2, and PXE3 and the common electrodes CE1, CE2, and CE3.

The pixel electrode layer may be formed as a single layer or multiple layers of molybdenum (Mo), aluminum (Al), chromium (Cr), gold (Au), titanium (Ti), nickel (Ni), neodymium (Nd), and/or copper (Cu), and/or alloys thereof. For example, the pixel electrode layer may be made of copper (Cu) having low surface resistance to lower the resistance of each of the pixel electrodes PXE1, PXE2, and PXE3.

A first organic layer 210 may be disposed on each of the pixel electrodes PXE1, PXE2, and PXE3 and the common electrodes CE1, CE2, and CE3. At least a portion of the pixel electrodes PXE1, PXE2, and PXE3 and the common electrodes CE1, CE2, and CE3 may be disposed on the first organic layer 210. The first organic layer 210 temporarily fixes or adheres the plurality of light emitting elements LE to prevent the plurality of light emitting elements LE from tilting and falling over or collapsing during a process of transferring the plurality of light emitting elements LE to the display panel 100. That is, the first organic layer 210 may be a film for temporarily adhering the plurality of light emitting elements LE onto each of the pixel electrodes PXE1, PXE2, and PXE3 and the common electrodes CE1, CE2, and CE3. To facilitate the temporary adhesion, the thickness of the first organic layer 210 may be greater than the thickness of each of the pixel electrodes PXE1, PXE2, and PXE3 and the common electrodes CE1, CE2, and CE3.

The first organic layer 210 may be a photosensitive organic layer such as photoresist. Alternatively, the first organic layer 210 may be formed from an acrylic resin, an epoxy resin, a phenolic resin, a polyamide resin, a polyimide resin, and/or the like.

The plurality of light emitting elements LE may be disposed on the first organic layer 210. In FIG. 6, each of the plurality of light emitting elements LE is a flip-type micro LED. The flip-type micro LED refers to an LED in which contact electrodes CTE1 and CTE2 are formed on one surface (e.g., the bottom surface) of the light emitting element LE.

Each of the plurality of light emitting elements LE may be formed by growing on a semiconductor substrate, such as a silicon substrate and/or a sapphire substrate. The plurality of light emitting elements LE may be transferred directly from a semiconductor substrate onto pixel electrodes PXE1, PXE2, and PXE3 and the common electrodes CE1, CE2, and CE3 of a display panel 100. Alternatively, the plurality of light emitting elements LE may be transferred onto pixel electrodes PXE1, PXE2, and PXE3 and the common electrodes CE1, CE2, and CE3 of a display panel 100 through an electrostatic method using an electrostatic head or a stamp method using an elastic polymer material such as polydimethylsiloxane (PDMS) and/or silicon as a transfer substrate.

The light emitting element LE may include a conductive layer E1, a semiconductor stack STC, contact electrodes CTE1 and CTE2, a passivation layer INS, and a selective reflection layer SRF. The semiconductor stack STC may include a first semiconductor layer SEM1, an active layer MQW, a second semiconductor layer SEM2, and a third semiconductor layer SEM3 sequentially disposed along the third direction DR3.

The conductive layer E1 may be disposed on the bottom surface of the first semiconductor layer SEM1. Although FIG. 7 illustrates that the conductive layer E1 covers the entire bottom surface of the first semiconductor layer SEM1, the present disclosure is not limited thereto. In one example, the conductive layer E1 may be disposed on a portion of the bottom surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

The first semiconductor layer SEM1 may be disposed on a conductive layer E1 (or on the first contact electrode CTE1 if the conductive layer E1 is omitted), the active layer MQW may be disposed on the first semiconductor layer SEM1, the second semiconductor layer SEM2 may be disposed on the active layer MQW, and the third semiconductor layer SEM3 may be disposed on the second semiconductor layer SEM2.

The first semiconductor layer SEM1 may be formed of GaN doped with a first conductive dopant (e.g., a p-type dopant) such as Mg, Zn, Ca, Sr, Ba, and/or the like.

The first semiconductor layer SEM1 may be electrically connected to the pixel electrode PXE of each sub-pixel SPX. For example, the first semiconductor layer SEM1 may be electrically connected to the pixel electrode PXE of each sub-pixel SPX through the conductive layer E1 and the first contact electrode CTE1.

The active layer MQW may be disposed on the first semiconductor layer SEM1. The active layer MQW may emit light by the coupling of electron-hole pairs according to an electric signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) and/or aluminum gallium nitride (AlGaN), but the present disclosure is not limited thereto. Alternatively, the active layer MQW may have a structure in which semiconductor materials having a high band gap energy and semiconductor materials having a low band gap energy are alternately stacked with each other, may include other Group III to V semiconductor materials according to the wavelength range of emitted light.

When the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (e.g., light in the blue wavelength band) may be approximately 10 wt % to 20 wt %.

The second semiconductor layer SEM2 may be disposed on the active layer MQW. The second semiconductor layer SEM2 may be doped with a second conductive dopant, such as Si, Ge, S n, and/or the like. For example, the second semiconductor layer SEM2 may be n-GaN doped with n-type Si.

The third semiconductor layer SEM3 may be disposed on the second semiconductor layer SEM2.

The third semiconductor layer SEM3 may be a semiconductor material layer having an n-type dopant lower than a suitable threshold value (e.g., a predetermined threshold value) and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN), where the n-type dopant is lower than a suitable threshold (e.g., a predetermined threshold).

An electron blocking layer may be disposed between the first semiconductor layer SEM1 and the active layer MQW. The electron blocking layer may be a layer for suppressing or preventing too many electrons from flowing into the active layer MQW. For example, the electron blocking layer may be AlGaN or p-AlGaN doped with p-type Mg. The electron blocking layer may be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be formed of InGaN and/or GaN. The superlattice layer may be omitted.

A light extraction patterns LEP may be formed on the top surface of the semiconductor stack STC. For example, the light extraction patterns LEP may be formed on the top surface of the third semiconductor layer SEM3.

The light extraction patterns LEP may be patterns for increasing the efficiency of light emitted to the top surface of the light emitting element LE. The light extraction patterns LEP may be concave patterns formed in a hemisphere or a semi-ellipse. The light extraction patterns LEP may be concave patterns having a cross-sectional shape of a semicircle or a semi-ellipse. The maximum length Lmax of the light extraction patterns LEP in the third direction DR3 may be approximately 100 nm. Further, the distance between adjacent light extraction patterns LEP may be approximately 100 nm or less.

The protective layer INS may be a film disposed on at least one side surface of the semiconductor stack STC and at least one side surface and the bottom surface of the conductive layer E1 to protect the light emitting element LE. Specifically, the protective layer INS is exemplified as being disposed on the bottom surface and side surfaces of the conductive layer E1, on the side surfaces of the first semiconductor layer SEM1, on the side surfaces of the active layer MQW, and on the side surfaces of the second semiconductor layer SEM2, but not disposed on the side surfaces of the third semiconductor layer SEM3, but the present disclosure is not limited thereto. In one example, the protective layer INS may be disposed on the side surfaces of the first semiconductor layer SEM1, on the side surfaces of the active layer MQW, and a portion of the side surface of the second semiconductor layer SEM2 of the semiconductor stack STC.

A hole LEH may be formed that penetrates the conductive layer E1, the first semiconductor layer SEM1, and the active layer MQW of the light emitting element LE to expose the second semiconductor layer SEM2. The hole LEH may have a circular planar shape, but the present disclosure is not limited thereto. For example, the hole LEH may have a planar shape of a polygon, such as an oval or a square.

In addition, the protective layer INS may be disposed on the sidewall of the conductive layer E1 exposed in the hole LEH, the sidewall of the first semiconductor layer SEM1 exposed in the hole LEH, and the sidewall of the active layer MQW exposed in the hole LEH and some portions of the sidewall of the second semiconductor layer SEM2 exposed in the hole LEH. The protective layer INS may not cover (e.g., may not completely cover) the second semiconductor layer SEM2 in the hole LEH. Therefore, the second semiconductor layer SEM2 may be exposed without being covered by the protective layer INS.

The protective layer INS may have two openings OP1 and OP2. The two openings OP1 and OP2 may be spaced (e.g., spaced apart) from each other. The first opening OP1 may be disposed on the first surface of the light emitting element LE, and the second opening OP2 may be disposed to overlap the bottom of the hole LEH. For example, the protective layer INS may be disposed on the sidewall of the conductive layer E1 exposed in the hole LEH, the sidewall of the first semiconductor layer SEM1, and the sidewall of the active layer MQW. The protective layer INS may not cover the second semiconductor layer SEM2 in the hole LEH. Therefore, the second semiconductor layer SEM2 may be exposed without being covered by the protective layer INS.

The protective layer INS may be disposed on one side and a portion of the sidewall of the light emitting element LE. For example, the protective layer INS may be disposed on at least one sidewall of the semiconductor stack STC, and at least one sidewall and the bottom surface of the conductive layer E1.

The protective layer INS may expose an area of the sidewall of the semiconductor stack STC that is adjacent to the top surface of the semiconductor stack STC without covering it. For example, the separation distance DS1 between the top surface of the semiconductor stack STC and the protective layer INS in the third direction DR3 may be greater than approximately 100 nm. Further, the separation distance DS1 between the top surface of the semiconductor stack STC and the protective layer INS in the third direction DR3 may be greater than the maximum length Lmax of the light extraction pattern in the third direction DR3. Here, the third direction DR3 may be substantially the same as the height direction (or thickness direction) of the light emitting element LE. In this way, when the protective layer INS is separated from the top surface of the semiconductor stack STC, the light emitting element LE may be easily separated from the base substrate on which the light emitting element LE is grown in the manufacturing process.

The protective layer INS may be formed from an inorganic film, for example, silicon nitride (SiNₓ), silicon oxide (SiON), silicon oxide (SiOₓ), titanium oxide (TiOₓ), and/or aluminum oxide (AlOₓ). In one or more embodiments, the insulating layer (INS) may be silicon oxide (SiOₓ).

The first contact electrode CTE1 may be disposed on at least one side of the semiconductor stack STC and at least one side and the bottom surface of the conductive layer E1. The first contact electrode CTE1 may be disposed on the bottom surface of the conductive layer E1 that is exposed and not covered by the protective layer INS (e.g., the first opening OP1). Therefore, the first contact electrode CTE1 may be electrically connected to the conductive layer E1 through the first opening OP1.

The second contact electrode CTE2 may be disposed on at least one side of the semiconductor stack STC and at least one side and the bottom surface of the conductive layer E1. At this time, the first contact electrode CTE1 may be disposed on the first side of the semiconductor stack STC and the first side of the conductive layer E1, while the second contact electrode CTE2 may be disposed on the second side of the semiconductor stack STC and the second side of the conductive layer E1.

The second contact electrode CTE2 may be disposed on the protective layer INS disposed in the hole LEH and the second semiconductor layer SEM2 exposed in the hole LEH without being covered by the protective layer INS. Therefore, the second contact electrode CTE2 may be electrically connected to the second semiconductor layer SEM2 in the hole LEH and the second opening OP2 of the protective layer INS.

The first contact electrode CTE1 and the second contact electrode CTE2 are not in contact with each other and are spaced from each other at the bottom surface of the conductive layer E1. Therefore, the first contact electrode CTE1 and the second contact electrode CTE2 are not electrically connected to each other.

The first contact electrode CTE1 and the second contact electrode CTE2 may include molybdenum (Mo), aluminum (Al), chromium (Cr), gold (Au), titanium (Ti), nickel (Ni), neodymium (Nd), and/or copper (Cu). Specifically, the plurality of contact electrodes CTE may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The selective reflection layer SRF may be disposed on the protective layer INS (e.g., between the protective layer INS and first contact electrode CTE1, and between the protective layer INS and the second contact electrode CTE2) and may be disposed on one surface of the conductive layer E1 and surrounding the side surfaces of the conductive layer E1 and the plurality of semiconductor layers SEM1, MQW, SEM2, and SEM3.

The selective reflection layer SRF may be disposed on the bottom surface and the side surface of the conductive layer E1 and the side surface of the semiconductor stack STC. The selective reflection layer SRF may reflect light emitted from the active layer MQW of the light emitting element LE to the top surface of the light emitting element LE. For example, the selective reflection layer SRF may be designed to primarily reflect light A1 of the first wavelength. The light A1 of the first wavelength may be light of a wavelength of 310 nm or less but is not limited thereto.

The selective reflection layer SRF may extend from the side surface of the light emitting element LE on the protective layer INS and may protrude outwardly from the top surface of the light emitting element LE. The protrusion direction may be the first direction DR1 perpendicular to the third direction DR3 which is the extension direction. For example, the selective reflection layer SRF may protrude outwardly perpendicular to the side surface of the light emitting element LE.

The selective reflection layer SRF may be disposed higher than the height of the protective layer INS.

A detailed description of the first selective reflection layer SRF will be described later with reference to FIGS. 8 and 9.

The connection electrodes BE include first connection electrodes BE1 and second connection electrodes BE2, and connects the contact electrodes CTE (e.g., CTE1, CTE2) of the light emitting element LE, and the pixel electrode PXE1, PXE2, and PXE3 and the common electrodes CE1, CE2, CE3. The first connection electrodes BE1 may be connected to the pixel electrodes PXE1, PXE2, and PXE3 exposed from the first organic layer 210. The second connection electrodes BE2 may be connected to the common electrodes CE1, CE2, and CE3 exposed from the first organic layer 210. Further, the connection electrodes BE (e.g., BE1 and BE2) may be disposed on the top surface of the first organic layer 210 and the contact electrodes CTE (e.g., CTE1 and CTE2).

The connection electrodes BE (e.g., BE1, BE2) may include molybdenum (Mo), aluminum (Al), chromium (Cr), gold (Au), titanium (Ti), nickel (Ni), neodymium (Nd), and/or copper (Cu). Alternatively, the connection electrodes BE (e.g., BE1, BE2) may be made of a transparent conductive material (TCO) such as indium tin oxide (ITO) and/or indium zinc oxide (IZO).

The connection electrodes BE (e.g., BE1, BE2) may be disposed on a side surface of the semiconductor stack STC. From among the side surfaces of the semiconductor stack STC, an area adjacent to the top surface of the semiconductor stack STC may be exposed without being covered by the connection electrodes BE (e.g., BE1, BE2). For example, the separation distance DS2 between the top surface of the semiconductor stack STC and the connection electrodes BE (e.g., BE1, BE2) in the third direction DR3 may be greater than approximately 100 nm. Further, the separation distance DS2 between the top surface of the semiconductor stack STC and the connection electrodes BE (e.g., BE1, BE2) in the third direction DR3 may be greater than the maximum length Lmax of the light extraction pattern LEP in the third direction DR3.

In one or more embodiments, the separation distance DS2 between the top surface of the semiconductor stack STC and the connection electrodes BE (e.g., BE1, BE2) in the third direction DR3 may be greater than the separation distance DS1 between the top surface of the semiconductor stack STC and the contact electrodes CTE (e.g., CTE1, CTE2) in the third direction DR3, but the present disclosure is not limited thereto. For example, the separation distance DS2 between the top surface of the semiconductor stack STC and the connection electrodes BE (e.g., BE1, BE2) in the third direction DR3 may be smaller than the separation distance DS1 between the top surface of the semiconductor stack STC and the contact electrodes CTE (e.g., CTE1, CTE2) in the third direction DR3. In this case, the connection electrodes BE (e.g., BE1, BE2) may cover at least a portion of the protective layer INS that is exposed and not covered by the contact electrode CTE. Alternatively, the connection electrodes BE (e.g., BE1, BE2) may be disposed to cover the entirety of the exposed protective layer INS that is not covered by the contact electrodes CTE (CTE1, CTE2). As another example, the separation distance DS2 between the top surface of the semiconductor stack STC and the connection electrodes BE (e.g., BE1, BE2) in the third direction DR3 may be substantially the same as the separation distance DS1 between the top surface of the semiconductor stack STC and the contact electrodes CTE (e.g., CTE1, CTE2) in the third direction DR3.

The second organic film 211 may be disposed to cover a side portion of the plurality of light emitting elements LE. Further, the second organic film 211 may be disposed to cover the connection electrodes BE (e.g., BE1, BE2).

The third organic film 212 may be disposed on the second organic film 211. The third organic film 212 may be disposed to cover another portion of the side surfaces of each of the plurality of light emitting elements LE. The third organic film 212 may be disposed on the protective layer INS, the contact electrodes CTE (e.g., CTE1, CTE2), and the connection electrodes BE (e.g., BE1, BE2) that are not covered by the second organic film 211 as shown in FIG. 7, but the present disclosure is not limited thereto. For example, the entire connection electrodes BE (e.g., BE1, BE2) may be covered by the second organic film 211. The top surface of each of the plurality of light emitting elements LE may be exposed without being covered by the third organic film 212.

The second organic film 211 and the third organic film 212 are layers for flattening the steps caused by the plurality of light emitting elements LE. If the height of the second organic film 211 is disposed to cover most of the side surfaces of each of the plurality of light emitting elements LE, the third organic film 212 may be omitted.

The second organic film 211 and the third organic film 212 may be formed from an organic film such as an acrylic resin, an epoxy resin, a phenolic resin, a polyamide resin, a polyimide resin, and/or the like.

The common electrodes CE1, CE2, CE3 may be made of a transparent conductive material (TCO), such as indium tin oxide (ITO) and/or indium zinc oxide (IZO), which may transmit light.

The pixel electrodes PXE1, PXE2, and PXE3 may be referred to as anode electrodes or first electrodes, and the common electrodes CE1, CE2, CE3 may be referred to as cathode electrodes or second electrodes.

A first capping layer CAP1 may be disposed on light emitting element LE (e.g., on the light extraction pattern LEP on the top surface of the light emitting element LE) and on the third organic film 212.

A light blocking layer BM (e.g., BM1, BM2), a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be formed by compartments the light blocking layer BM (e.g., BM1, BM2). Therefore, the first light conversion layer QDL1 may be disposed on the first capping layer CAP1 in the first sub-pixel SPX1, the second light conversion layer QDL2 may be disposed on the first capping layer CAP1 in the second sub-pixel SPX2, and the light transmission layer TPL may be disposed on the first capping layer CAP1 in the third sub-pixel SPX3. The light blocking layer BM (e.g., BM1, BM2) may not overlap the plurality of light emitting elements LE in the third direction DR3.

The first light conversion layer QDL1 may convert a portion of the third light (e.g., light in the blue wavelength band) incident from the light emitting element LE into first light (e.g., light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (e.g., light in the blue wavelength band) incident from the light emitting element LE into first light (e.g., light in the red wavelength band).

The second light conversion layer QDL2 may convert a portion of the third light (e.g., light in the blue wavelength band) incident from the light emitting element LE into second light (e.g., light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (e.g., light in the blue wavelength band) incident from the light emitting element LE into second light (e.g., light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cardo-based resin, and/or an imide-based resin. The first and second wavelength conversion particles WCP1 and WCP2 may be quantum dots (QD), quantum rods, fluorescent materials, and/or phosphorescent materials.

The light blocking layer BM may include a first light blocking layer BM1 and a second light blocking layer BM2 that are sequentially stacked. A length of the first light blocking layer BM1 in the first direction DR1 or a length in the second direction DR2 may be wider than a length of the second light blocking layer BM2 in the first direction DR1 or a length in the second direction DR2 of the second light blocking layer BM2. The first light blocking layer BM1 and the second light blocking layer BM2 may be formed of an organic film such as an acrylic resin, an epoxy resin, a phenolic resin, a polyamide resin, a polyimide resin, and/or the like. The first light blocking layer BM1 and the second light blocking layer BM2 may include a light blocking material to prevent light from the light emitting element LE of one sub-pixel from proceeding to the neighboring sub-pixel. For example, the first light blocking layer BM1 and the second light blocking layer BM2 may include an inorganic black pigment such as carbon black and/or an organic black pigment.

The second capping layer CAP2 may be disposed on the first capping layer CAP1 and the light blocking layer BM. The second capping layer CAP2 may be disposed on the side and top surfaces of the light blocking layer BM. That is, the second capping layer CAP2 may be disposed on the side of the first light blocking layer BM1 and the side and top surfaces of the second light blocking layer BM2.

The reflective film RF may be disposed between the light blocking layer BM and the first light conversion layer QDL1, between the light blocking layer BM and the second light conversion layer QDL2, and between the light blocking layer BM and the light transmission layer TPL. The reflective film RF may be disposed on a second capping layer CAP2 disposed on the side of the first light blocking layer BM1 and the side of the second light blocking layer BM2. The reflective film RF serves to reflect light traveling in the lateral direction from the first light conversion layer QDL1, the second light conversion layer QDL2, and the light transmission layer TPL.

The reflective film RF may include a highly reflective metal material such as aluminum (Al). The thickness of the reflective film RF may be approximately 0.1 μm.

Alternatively, the reflective layer RF may include a first layer and a second layer of M (M is an integer of 2 or more) pairs having different refractive indices to serve as Distributed Bragg Reflectors (DBR). In this case, the M first layers and the M second layers may be disposed alternately. In the same pair, the first layer may be disposed closer to the inside of the light emitting element than the second layer, and the refractive index of the first layer may be lower than the refractive index of the second layer. The difference between the refractive index of the first layer and the refractive index of the second layer may be 0.55 or more.

The first layer and the second layer may be formed of an inorganic film, for example, silicon nitride (SiNₓ), silicon oxide (SiON), silicon oxide (SiOₓ), titanium oxide (TiOₓ), and/or aluminum oxide (AlOₓ).

The third capping layer CAP3 may be disposed on the second capping layer CAP2, the first light conversion layer QDL1, the second light conversion layer QDL2, and the light transmission layer TPL.

The first capping layer CAP1, the second capping layer CAP2, and the third capping layer CAP3 may be formed of an inorganic film, for example, silicon nitride (SiNₓ), silicon oxide (SiON), silicon oxide (SiOₓ), titanium oxide (TiOₓ), and/or aluminum oxide (AlOₓ). The first light conversion layer QDL1, the second light conversion layer QDL2, and the light transmission layer TPL may be encapsulated by the first capping layer CAP1, the second capping layer CAP2, and the third capping layer CAP3.

A fourth organic film 213 may be disposed on the third capping layer CAP3. A plurality of color filters CF1, CF2, and CF3 may be disposed on the fourth organic film 213. The plurality of color filters CF1, CF2, and CF3 may include first color filters CF1, second color filters CF2, and third color filters CF3.

The first color filter CF1 disposed in the first sub-pixel SPX1 may transmit the first light (e.g., light in the red wavelength band) and absorb or block the third light (e.g., light in the blue wavelength band). Therefore, the first color filter CF1 may transmit the first light (e.g., light in the red wavelength band) converted by the first light conversion layer QDL1 from among the third light (e.g., light in the blue wavelength band) emitted from the light emitting element LE and absorb or block the third light (e.g., light in the blue wavelength band) not converted by the first light conversion layer QDL1. Accordingly, the first sub-pixel SPX1 may emit the first light (e.g., light in the red wavelength band).

The second color filter CF2 disposed in the second sub-pixel SPX2 may transmit the second light (e.g., light in the green wavelength band) and absorb or block the third light (e.g., light in the blue wavelength band). Therefore, the second color filter CF2 may transmit the second light (e.g., light in the green wavelength band) converted by the first light conversion layer QDL1 from among the third light (e.g., light in the blue wavelength band) emitted from the light emitting element LE and absorb or block the third light (e.g., light in the blue wavelength band) not converted by the first light conversion layer QDL1. Accordingly, the second sub-pixel SPX2 may emit the second light (e.g., light in the green wavelength band).

The third color filter CF3 disposed in the third sub-pixel SPX3 may transmit the third light (e.g., light in the blue wavelength band). Therefore, the third color filter CF3 may transmit the third light (e.g., light in the blue wavelength band) emitted from the light emitting element LE passing through the light transmission layer TPL. Accordingly, the third sub-pixel SPX3 may emit the third light (e.g., light in the blue wavelength band).

The first color filter CF1, the second color filter CF2, and the third color filter CF3 overlapping in the third direction DR3 may overlap with the light blocking layer BM and the light blocking layer BM in the third direction DR3.

A fifth organic film 214 may be disposed on the plurality of color filters CF1, CF2, and CF3 for planarization.

The fourth organic film 213 and the fifth organic film 214 may be formed from an acrylic resin, an epoxy resin, a phenolic resin, a polyamide resin, a polyimide resin, and/or the like.

FIG. 8 is a drawing illustrating an enlarged view of an area B of FIG. 7. FIG. 9 is a drawing illustrating an enlarged view of an area B of FIG. 7 according to another example.

Referring to FIG. 8 and FIG. 9, one example of a selective reflection film may be confirmed in detail.

Referring to FIG. 8 and FIG. 9, the selective reflection layer SRF may act as a distributed Bragg reflector. That is, the selective reflection layer SRF may reflect light of a first wavelength and transmit light of another wavelength. The first wavelength may be a target reflection wavelength that the selective reflection layer SRF intends to reflect.

F or the selective reflection layer SRF to act as a distributed Bragg reflector (DBR), it includes M pairs of first layers LL1 and second layers LL2 (M is an integer greater than or equal to 2). The M first layers LL1 and M second layers LL2 may be disposed alternately. In each of the M pairs, the first layer LL1 may be disposed adjacent to the light emitting element LE relative to the second layer LL2. For example, the three pairs of the first layer LL1 and the second layer LL2 of the selective reflection layer SRF may be disposed in the order of the semiconductor stack STC, the protective layer INS, the first layer LL1, the second layer LL2, the first layer LL1, the second layer LL2, the first layer LL1, the second layer LL2.

The selective reflection layer SRF may include the first layer and the second layer of the M pairs (M is an integer greater than or equal to 2) having different refractive indices to act as distributed Bragg reflectors (DBR). In this case, the M first layers and the M second layers may be disposed alternately. The first layer and the second layer may be formed of an inorganic film, such as silicon nitride (SiNₓ), silicon oxide (SiON), silicon oxide (SiOₓ), titanium oxide (TiOₓ), and/or aluminum oxide (AlOₓ).

In each of the M pairs, the first layer LL1 may include a material such as a protective layer INS. The first layer LL1 and the protective layer INS may be etched by the first etching, while the second layer LL2 may not be etched by the first etching. For example, the first layer LL1 and the protective layer INS may be formed of silicon oxide (SiOₓ), and the second layer LL2 may be formed of titanium oxide (TiOₓ).

In each of the M pairs, the first layer LL1 may be formed shorter than the second layer LL2.

In each of the M pairs, the first layer LL1 may be spaced (e.g., spaced apart) from one end of the light emitting element LE.

The first layers LL1 of the M pair may have different lengths. For example, the first layers LL1 may be formed longer as they are further from the light emitting element LE, but the present disclosure is not limited thereto.

For example, referring to FIG. 8, a first pair, a second pair, and a third pair are disposed in an outward direction from the light emitting element LE. The first layer LL1 of the first pair may have the same height (e.g., in the third direction DR3) as the protective layer INS. On the other hand, the first layer LL1 of the second pair may be longer than the first layer LL1 of the first pair, and the first layer LL1 of the third pair may be longer than the first layer LL1 of the second pair.

In addition, the second layer LL2 may protrude outwardly from the top surface of the light emitting element LE. The protrusion direction may be the first direction DR1 that is perpendicular to the third direction DR3, which is the extension direction of the light emitting element LE. For example, the second layer LL2 may protrude outwardly perpendicular to the side surface of the light emitting element LE. On the other hand, the first layer LL1 may not protrude outwardly perpendicular to the side surface of the light emitting element LE.

Referring to FIG. 9, the first layer LL1 disposed closest to the light emitting element LE may have the same height as the protective layer INS. On the other hand, the first layer LL1 disposed farthest from the light emitting element LE is longer than the first layer LL1 disposed closest to the light emitting element LE. On the other hand, the length of the first layer LL1 disposed in the middle may be the longest.

When the light extraction pattern LEP is included on the top surface of the light emitting element LE, the selective reflection layer SRF adjacent to the top surface of the light emitting element LE may also follow the shape of the light extraction pattern LEP. In one or more embodiments, the selective reflection layer SRF may include a portion of a concave pattern having a cross-sectional shape of a semicircle or a semi-ellipse.

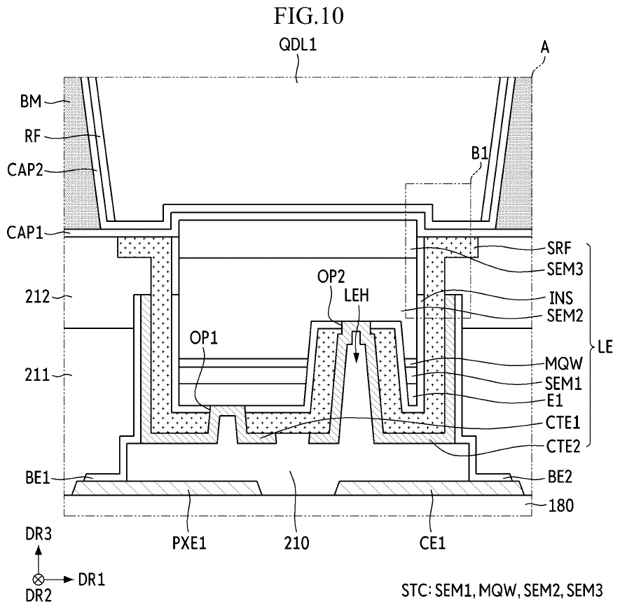

FIG. 10 is a cross-sectional view illustrating another example of the area A of FIG. 6 in detail.

The embodiment of FIG. 10 differs from the embodiment of FIG. 7 in that the light emitting element LE does not include a light extraction pattern LEP. In FIG. 10, descriptions that overlap with the embodiment of FIG. 7 will be omitted, and differences from the embodiment of FIG. 7 will be mainly described.

Referring to FIG. 10, the top of the semiconductor stack STC does not include a light extraction pattern LEP. In the example of FIG. 10, the semiconductor stack STC includes, but is not limited to, a first semiconductor layer SEM1, an active layer MQW, a second semiconductor layer SEM2, and a third semiconductor layer SEM3. The semiconductor stack STC may include the first semiconductor layer SEM1, the active layer MQW, and the second semiconductor layer SEM2, and may not include the third semiconductor layer SEM3.

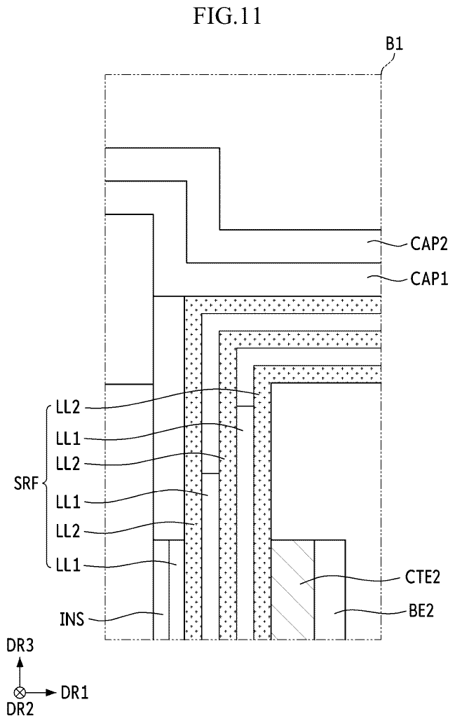

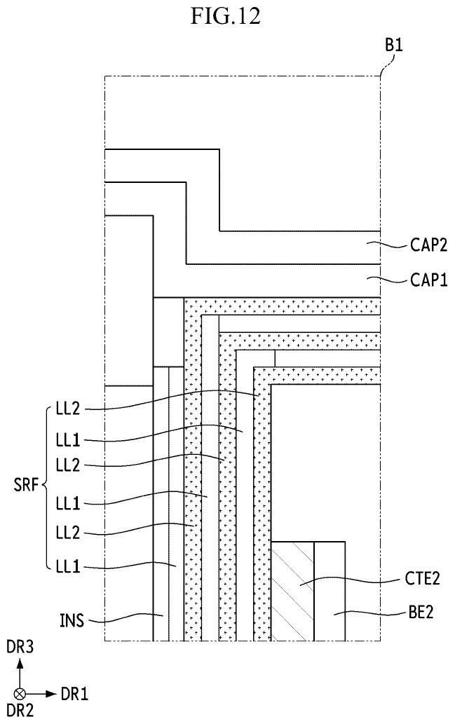

FIG. 11 is a drawing illustrating an enlarged view of an area B1 of FIG. 10. FIG. 12 is a drawing illustrating another example illustrating an enlarged view of the area B1 of FIG. 7.

FIGS. 11 and 12 differ from the embodiments of FIGS. 8 and 9 in that the light emitting element LE does not include a light extraction pattern LEP. In FIGS. 11 and 12, descriptions that overlap with the embodiments of FIGS. 8 and 9 will be omitted, and differences from the embodiments of FIGS. 8 and 9 will be mainly described.

Because the light emitting element LE does not include a light extraction pattern LEP, the selective reflection layer SRF adjacent to the top surface of the light emitting element LE also does not include a concave pattern and may be formed parallel to one end of the light emitting element LE.

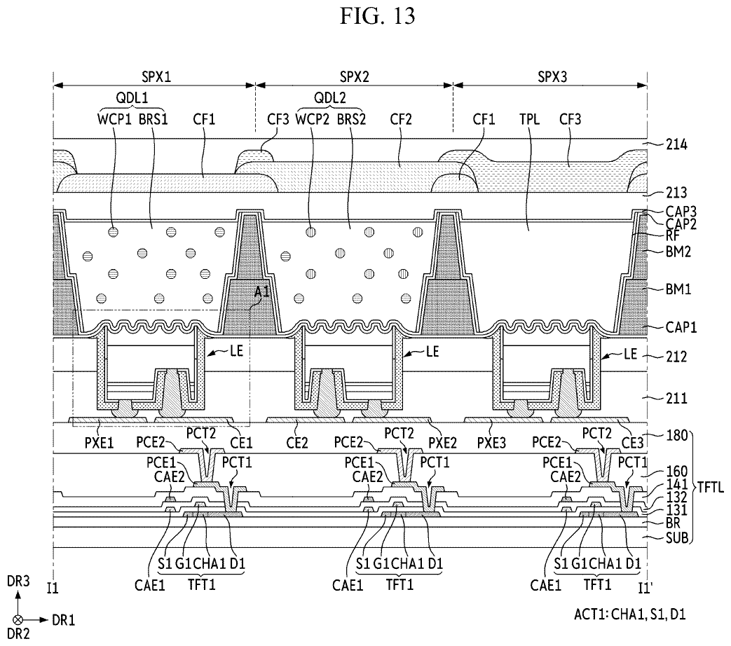

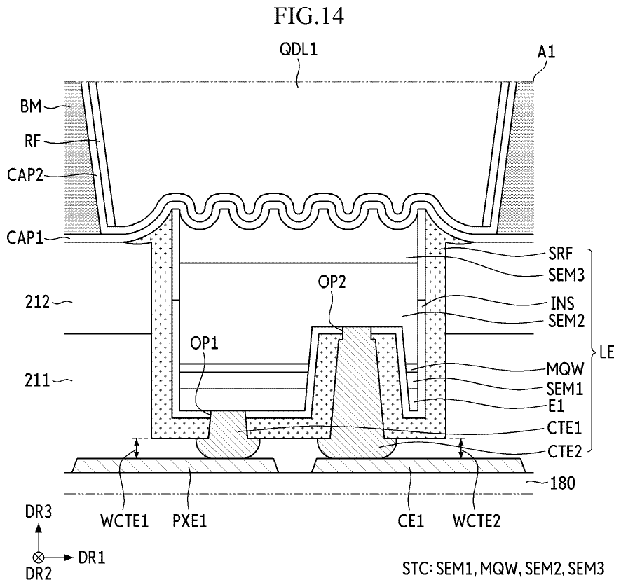

FIG. 13 is a cross-sectional view illustrating another example of a cross-section of a display panel corresponding to the lines I1-I1′ of FIG. 5. FIG. 14 is a cross-sectional view illustrating in detail an example of an area A1 of FIG. 13

The embodiments of FIGS. 13 and 14 differ from the embodiments of FIGS. 6 and 7 in that the first organic layer 210 and the connection electrodes BE are omitted, and the first and second contact electrodes CTE1 and CTE2, and the pixel electrodes PXE1, PXE2, and PXE3 and the common electrode CE1, CE2, and CE3 are directly connected. In FIGS. 13 and 14, overlapping descriptions with the embodiments of FIGS. 6 and 7 are omitted, and differences from the embodiments of FIGS. 6 and 7 are mainly described.

Referring to FIGS. 13 and 14, the contact electrodes CTE1 and CTE2 may have a pillar shape.

The first contact electrode CTE1 may be disposed on the conductive layer E1 exposed in the first opening OP1 of the protective layer INS. The first contact electrode CTE1 may be formed to protrude outwardly (e.g., downwardly) from the conductive layer E1.

The first contact electrode CTE1 may be disposed on the pixel electrodes PXE1, PXE2, and PXE3 and may be electrically connected to each other.

The second contact electrode CTE2 may be disposed on the second semiconductor layer SEM2 exposed from the second opening OP2 of the protective layer INS provided in the hole LEH. The second contact electrode CTE2 may be formed to protrude outwardly (e.g., downwardly) from the second semiconductor layer SEM2.

The second contact electrode CTE2 may be disposed on the common electrodes CE1, CE2, and CE3 and may be electrically connected to each other.

A protrusion length WCTE1 of the first contact electrode CTE1 and a protrusion length WCTE2 of the second contact electrode CTE2 may be the same but are not limited thereto. When the protrusion length WCTE1 of the first contact electrode CTE1 and the protrusion length WCTE2 of the second contact electrode CTE2 are the same, the light emitting element LE may be stably disposed on the pixel electrodes PXE1, PXE2, and PXE3 and the common electrode CE1, CE2, and CE3 without tilting.

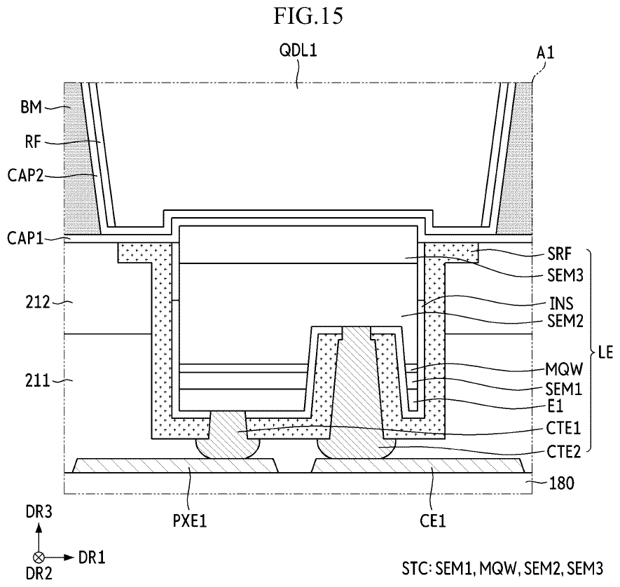

FIG. 15 is a cross-sectional view illustrating another example of the area A1 of FIG. 13 in detail.

The embodiment of FIG. 15 differs from the embodiment of FIG. 14 in that the light emitting element LE does not include a light extraction pattern LEP. In FIG. 15, descriptions that overlap with the embodiment of FIG. 14 will be omitted, and differences from the embodiment of FIG. 14 will be mainly described.

Referring to FIG. 15, the top of the semiconductor stack STC does not include a light extraction pattern LEP. In the example of FIG. 15, the semiconductor stack STC includes, but is not limited to, a first semiconductor layer SEM1, an active layer MQW, a second semiconductor layer SEM2, and a third semiconductor layer SEM3. The semiconductor stack STC may include the first semiconductor layer SEM1, the active layer MQW, and the second semiconductor layer SEM2, and may not include the third semiconductor layer SEM3.

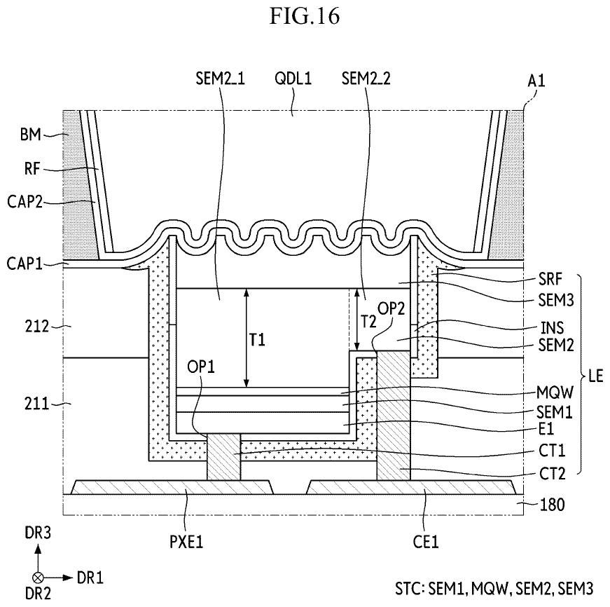

FIG. 16 is a cross-sectional view illustrating another example of the area A1 of FIG. 13 in detail.

The embodiment of FIG. 16 is different from the embodiment of FIG. 14 in the shape of the semiconductor stack STC of the light emitting element LE. In FIG. 16, descriptions that overlap with the embodiment of FIG. 14 will be omitted, and differences from the embodiment of FIG. 14 will be mainly described.

Referring to FIG. 16, the light emitting element LE may include a conductive layer E1, a semiconductor stack STC, a first electrode CT1, a second electrode CT2, a protective layer INS, and a selective reflection layer SRF. The semiconductor stack STC may include a first semiconductor layer SEM1, an active layer MQW, a second semiconductor layer SEM2, and a third semiconductor layer SEM3 that are sequentially arranged along a third direction DR3.

The conductive layer E1 may be disposed on the bottom surface of the first semiconductor layer SEM1.

The first semiconductor layer SEM1 may be formed of GaN doped with a first conductive dopant (e.g., a p-type dopant) such as Mg, Zn, Ca, Sr, Ba, and/or the like.

The first semiconductor layer SEM1 may be electrically connected to the pixel electrode PXE1 through the conductive layer E1 and the first electrode CT1.

The active layer MQW may be disposed on the first semiconductor layer SEM1. The active layer MQW may emit light by the combination of electron-hole pairs according to an electric signal applied through the first semiconductor layer SEM1 and the second semiconductor layer SEM2.

The second semiconductor layer SEM2 may be disposed on the active layer MQW. The second semiconductor layer SEM2 may be doped with a second conductive dopant, such as Si, Ge, S n, and/or the like. For example, the second semiconductor layer SEM2 may be n-GaN doped with n-type Si. The second semiconductor layer SEM2 may include a first portion SEM2_1 having a first thickness T1 and a second portion SEM2_2 having a second thickness T2 smaller than the first thickness T1.

The first portion SEM2_1 of the second semiconductor layer SEM2 may be disposed on the active layer MQW.

The third semiconductor layer SEM3 may be disposed on the second semiconductor layer SEM2. The third semiconductor layer SEM3 may be disposed on the first portion SEM2_1 and the second portion SEM2_2.

The third semiconductor layer SEM3 may be formed as a semiconductor layer that is not doped with an n-type dopant or a p-type dopant, i.e., an undoped semiconductor layer. For example, the third semiconductor layer SEM3 may be undoped InAlGaN, GaN, AlGaN, InGaN, AlN, and/or InN. For example, the third semiconductor layer SEM3 may be undoped GaN.

The light extraction patterns LEP may be formed on the top surface of the semiconductor stack STC. For example, the light extraction patterns LEP may be formed on the top surface of the third semiconductor layer SEM3.

The electron blocking layer may be disposed between the first semiconductor layer SEM1 and the active layer MQW. The electron blocking layer may be a layer for suppressing or preventing too many electrons from flowing into the active layer MQW. For example, the electron blocking layer may be AlGaN and/or p-AlGaN doped with p-type Mg. The electron blocking layer may be omitted.

The superlattice layer may be disposed between the active layer MQW and the second semiconductor layer SEM2. The superlattice layer may be a layer for relieving stress between the second semiconductor layer SEM2 and the active layer MQW. For example, the superlattice layer may be formed of InGaN and/or GaN. The superlattice layer may be omitted.

The protective layer INS may be a film for protecting the light emitting element LE by being disposed on at least one side of the semiconductor stack STC and at least one side and the lower surface of the conductive layer E1. Specifically, the protective layer INS is disposed on the bottom surface and the side surface of the conductive layer E1, on the side surface of the first semiconductor layer SEM1, on the side surfaces of the active layer MQW, and on the side surfaces of the second semiconductor layer SEM2 and not on the side surfaces of the third semiconductor layer SEM3, but the present disclosure is not limited thereto. In one example, the protective layer INS may be disposed on the side surfaces of the first semiconductor layer SEM1 of the semiconductor stack STC, the side surfaces of the active layer MQW, and a portion of the side surface of the second semiconductor layer SEM2.

The protective layer INS may have two openings OP1 and OP2. The two openings OP1 and OP2 may be spaced (e.g., spaced apart) from each other. The first opening OP1 may be disposed on the conductive layer E1 to expose the conductive layer E1. The second opening OP2 may be disposed on the second semiconductor layer SEM2. For example, the second opening OP2 may be disposed on the second portion SEM2_2 to expose the second semiconductor layer SEM2.

The protective layer INS may expose an area of the side surface of the semiconductor stack STC that is adjacent to the top surface of the semiconductor stack STC without covering it.

The protective layer INS may be formed of an inorganic film, such as silicon nitride (SiNₓ), silicon oxide (SiON), silicon oxide (SiOₓ), titanium oxide (TiOₓ), and/or aluminum oxide (AlOₓ). In one or more embodiments, the protective layer INS may be silicon oxide (SiOₓ).

The first electrode CT1 may be disposed on at least a portion of the conductive layer E1. The first electrode CT1 is connected to the conductive layer E1 through the first opening OP1.

The first electrode CT1 may include molybdenum (Mo), aluminum (Al), chromium (Cr), gold (Au), titanium (Ti), nickel (Ni), neodymium (Nd), and/or copper (Cu).

The second electrode CT2 may be disposed on at least a portion of the second portion SEM2_2 of the second semiconductor layer SEM2. The second electrode CT2 may be connected to the second semiconductor layer SEM2 through the second opening OP2.

Not only is the active layer MQW and the first semiconductor layer SEM1 not disposed on the second portion SEM2_2 of the second semiconductor layer SEM2, but also the thickness T2 of the second portion SEM2_2 of the second semiconductor layer SEM2 is smaller than the thickness T1 of the first portion SEM2_1. Therefore, to compensate for the thickness difference between the first portion SEM2_1 and the second portion SEM2_2 of the second semiconductor layer SEM2, the thickness of the active layer MQW, and the thickness of the first semiconductor layer SEM1, the thickness of the second electrode CT2 may be greater than the thickness of the first electrode CT1. For example, the thickness of the second electrode CT2 may be greater than or equal to the sum of the thickness difference between the first portion SEM2_1 and the second portion SEM2_2 of the second semiconductor layer SEM2, the thickness of the active layer MQW, the thickness of the first semiconductor layer SEM1, and the thickness of the conductive layer E1.

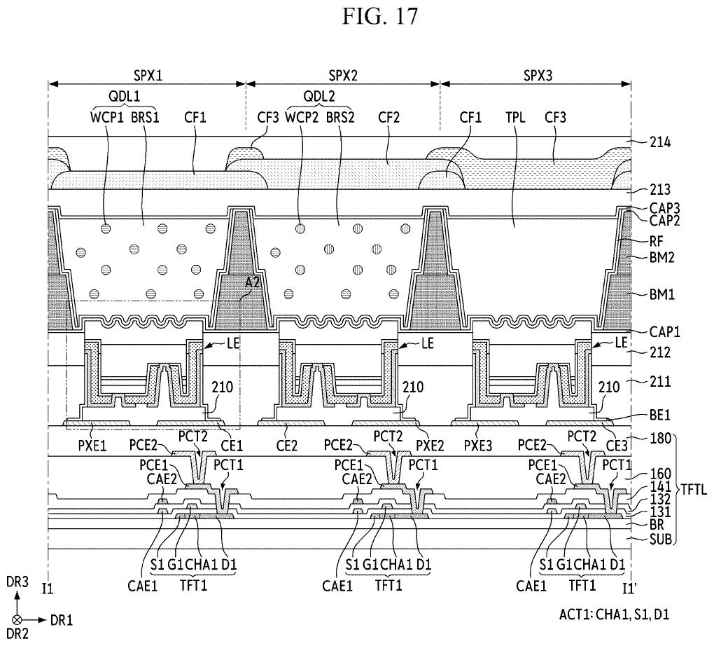

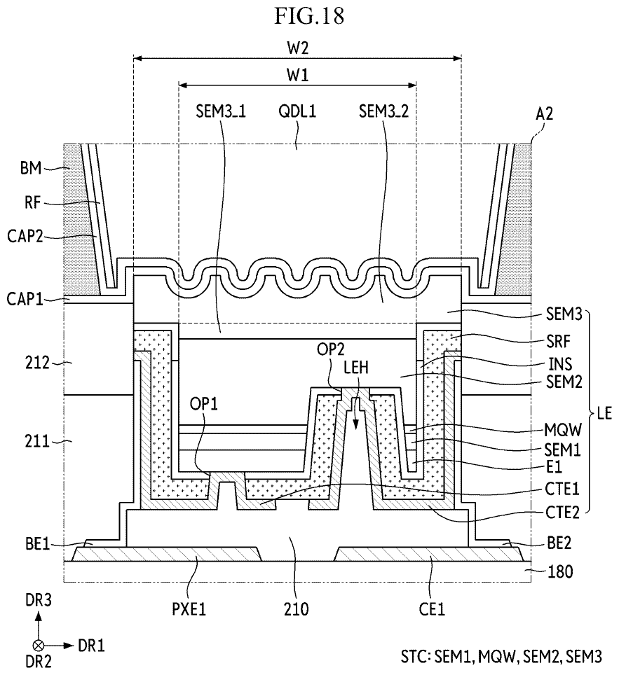

FIG. 17 is a cross-sectional view illustrating another example of a cross-section of a display panel corresponding to the line I1-I1′ of FIG. 5. FIG. 18 is a cross-sectional view illustrating an example of an area A2 of FIG. 17 in detail.

The embodiments of FIGS. 17 and 18 differ from the embodiments of FIGS. 6 and 7 in that the third semiconductor layer SEM3 has a first portion SEM3_1 and a second portion SEM3_2 having different widths, and a protective layer INS and a selective reflection layer SRF are not disposed on the side surface of the second portion SEM3_2 of the third semiconductor layer SEM3. In FIGS. 17 and 18, descriptions that overlap with the embodiments of FIGS. 6 and 7 will be omitted, and differences from the embodiments of FIGS. 6 and 7 will be mainly described.

Referring to FIGS. 17 and 18, the third semiconductor layer SEM3 may be disposed on the second semiconductor layer SEM2. The third semiconductor layer SEM3 may be formed as a semiconductor layer that is not doped with an n-type dopant or a p-type dopant, i.e., an undoped semiconductor layer. The third semiconductor layer SEM3 may include a first portion SEM3_1 having a first width W1 and a second portion SEM3_2 having a second width W2. The second width W2 may be wider than the first width W1. The first portion SEM3_1 of the third semiconductor layer SEM3 may be disposed on the second semiconductor layer SEM2, and the second portion SEM3_2 may be disposed on the first portion SEM3_2.

The side surfaces of the second semiconductor layer SEM2, the active layer MQW, the first semiconductor layer SEM1, and the first portion SEM3_1 of the third semiconductor layer SEM3 may be mutually aligned and coincident.

The second portion SEM3_2 of the third semiconductor layer SEM3 may protrude outwardly from the first portion SEM3_1.

The protective layer INS is disposed on the bottom surface and side surface of the conductive layer E1, the side surface of the first semiconductor layer SEM1, the side surface of the active layer MQW, the side surface of the second semiconductor layer SEM2, and the side surface of the first portion SEM3_1 of the third semiconductor layer SEM3, and may be disposed on a portion of one surface of the second portion SEM3_2 of the third semiconductor layer SEM3. A portion of the second portion SEM3_2 may be a non-overlapping portion of the first portion SEM3_1. The protective layer INS may expose the side surface of the second portion SEM3_2 of the third semiconductor layer SEM3 without covering it. In this way, when the side surface of the second portion SEM3_2 of the third semiconductor layer SEM3 is not covered, the light emitting element LE may be easily separated from the base substrate on which the light emitting element LE is grown during the manufacturing process.

The protective layer INS may have two openings OP1 and OP2. The two openings OP1 and OP2 may be spaced (e.g., spaced apart) from each other. The first opening OP1 may be disposed on the first surface of the light emitting element LE, and the second opening OP2 may be disposed to overlap the bottom of the hole LEH. For example, the protective layer INS may be disposed on the sidewall of the conductive layer E1 exposed in the hole LEH, the sidewall of the first semiconductor layer SEM1 exposed in the hole LEH, and the sidewall of the active layer MQW exposed in the hole LEH. The protective layer INS may not cover (e.g., may not completely cover) the second semiconductor layer SEM2 in the hole LEH. Therefore, the second semiconductor layer SEM2 may be exposed without being covered by the protective layer INS.

The selective reflection layer SRF may be disposed on the protective layer INS and may be disposed on a first side of the conductive layer E1, surrounding the conductive layer E1 and the sides of the plurality of semiconductor layers SEM1, MQW, SEM2, and SEM3_1. Further, the selective reflection layer SRF may be disposed on a portion of one surface of the second portion SEM3_2 of the third semiconductor layer SEM3. A portion of the second portion SEM3_2 may be a portion that does not overlap with the first portion SEM3_1.

The selective reflection layer SRF may be disposed on the protective layer INS and may be disposed on a first surface of the conductive layer E1 surrounding the conductive layer E1 and the sides of the plurality of semiconductor layers SEM1, MQW, SEM2, and SEM3_1. Further, the selective reflection layer SRF may be disposed on a portion of one surface of the second portion SEM3_2 of the third semiconductor layer SEM3. A portion of the second portion SEM3_2 may not overlap with the first portion SEM3_1.

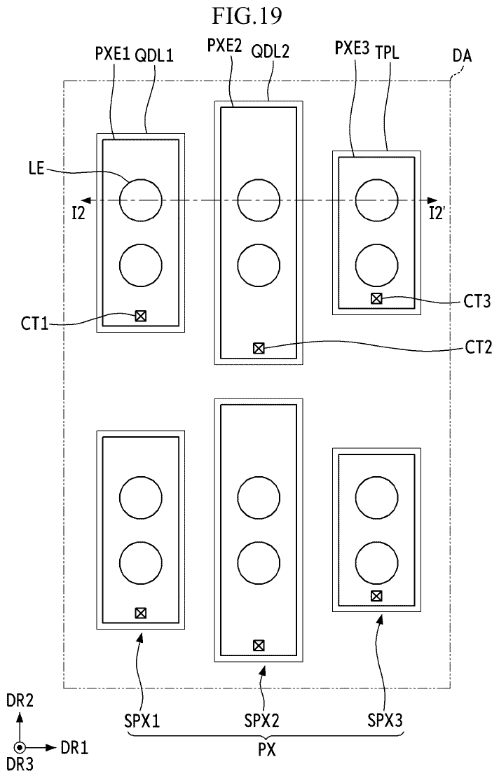

FIG. 19 is a layout diagram illustrating pixels of the display area according to one or more embodiments.

The embodiment of FIG. 19 differs from the embodiment of FIG. 5 in that the light emitting elements LE overlap the pixel electrodes PXE1, PXE2, and PXE3 in each of the first sub-pixel SPX1, the second sub-pixel SPX2, and the third sub-pixel SPX3. In the embodiment of FIG. 19, the description overlapping with the embodiment of FIG. 5 is omitted.

Referring to FIG. 19, the first sub-pixel SPX1 includes a first pixel electrode PXE1, a plurality of light emitting elements LE, and a first light conversion layer QDL1. The second sub-pixel SPX2 includes a second pixel electrode PXE2, a plurality of light emitting elements LE, and a second light conversion layer QDL2. The third sub-pixel SPX3 includes a third pixel electrode PXE3, a plurality of light emitting elements LE, and a light transmission layer (or third light conversion layer) TPL.

Each of the first pixel electrode PXE1, the second pixel electrode PXE2, and the third pixel electrode PXE3 may have a rectangular planar shape having a short side in the first direction DR1 and a long side in the second direction DR2. The area of the first sub-pixel SPX1, the area of the second sub-pixel SPX2, and the area of the third sub-pixel SPX3 may be set according to the light conversion efficiency of the first light conversion layer QDL1 and the light conversion efficiency of the second light conversion layer QDL2. In one example, the area of the sub-pixel may be larger as the light conversion efficiency is lower.

For example, as shown in FIG. 19, when the light conversion efficiency of the second light conversion layer QDL2 is lower than the light conversion efficiency of the first light conversion layer QDL1, the area of the second pixel electrode PXE2 may be larger than the area of the first pixel electrode PXE1. Furthermore, because the light transmission layer TPL directly transmits the light of the light emitting element LE, while the area of the first pixel electrode PXE1 may be larger than the area of the third pixel electrode PXE3 because the first light conversion layer QDL1 need to convert the light.

Each of the pixel electrodes PXE1, PXE2, and PXE3 may be electrically connected to at least one transistor through a pixel connection hole CT1, CT2, and CT3. For example, each of the pixel electrodes PXE1, PXE2, and PXE3 may be electrically connected to the first electrode of the fourth transistor (ST4 in FIG. 4) of the corresponding sub-pixel and the second electrode of the sixth transistor (ST6 in FIG. 4).

The plurality of light emitting elements LE may be disposed on each of the pixel electrodes PXE1, PXE2, and PXE3. The same number of light emitting elements LE may be disposed on each of the pixel electrodes PXE1, PXE2, and PXE3. For example, two light emitting elements LE may be disposed on each of the pixel electrodes PXE1, PXE2, and PXE3.

The first light conversion layer QDL1 may completely overlap the first pixel electrode PXE1 and the plurality of light emitting elements LE of the first sub-pixel SPX1. The area of the first light conversion layer QDL1 may be larger than the area of the first pixel electrode PXE1. The first light conversion layer QDL1 may convert or shift the peak wavelength of incident light into light of another specific peak wavelength and emit it. For example, the first light conversion layer QDL1 may convert or shift the third light emitted from the plurality of light emitting elements LE of the first sub-pixel SPX1 into first light.

The second light conversion layer QDL2 may completely overlap the plurality of light emitting elements LE of the second pixel electrode PXE2 and the second sub-pixel SPX2. The area of the second light conversion layer QDL2 may be larger than the area of the second pixel electrode PXE2. The second light conversion layer QDL2 may convert or shift the peak wavelength of incident light into light of another specific peak wavelength and emit it. For example, the second light conversion layer QDL2 may convert or shift the third light emitted from the plurality of light emitting elements LE of the second sub-pixel SPX2 into second light.

The light transmission layer TPL may completely overlap the plurality of light emitting elements LE of the third pixel electrode PXE3 and the third sub-pixel SPX3. The light transmission layer TPL may transmit incident light as it is. For example, the light transmission layer TPL may directly transmit the third light emitted from the plurality of light emitting elements LE of the third sub-pixel SPX3.

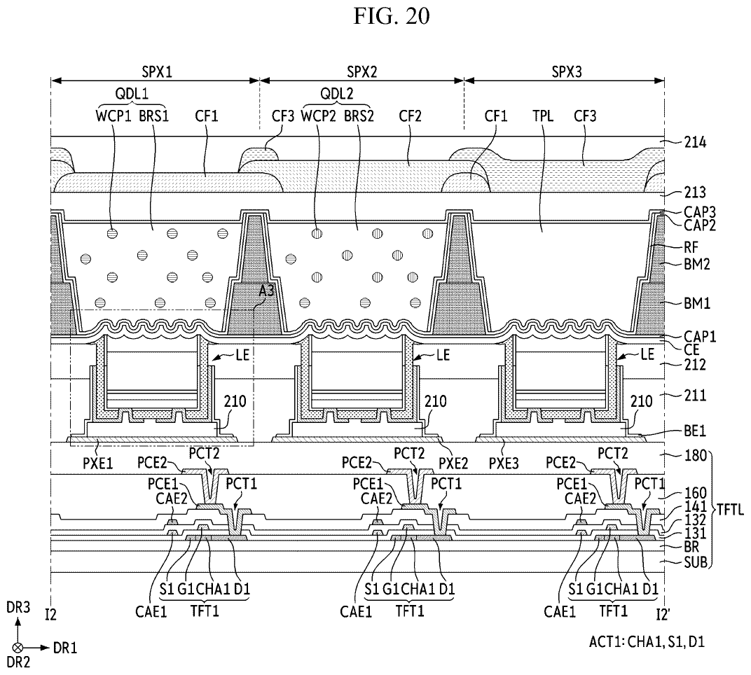

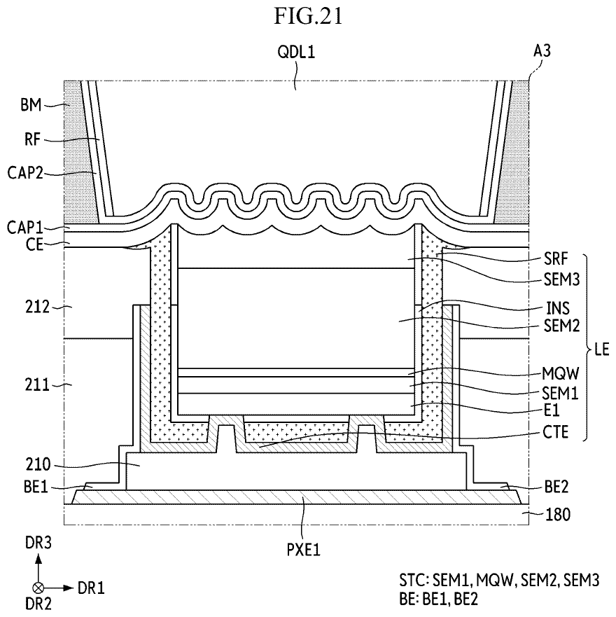

FIG. 20 is a cross-sectional view illustrating an example of the cross-section of the display panel corresponding to the line I2-I2′ of FIG. 19. FIG. 21 is a cross-sectional view illustrating an example of an area A3 of FIG. 20 in detail.

The embodiments of FIGS. 20 and 21 differ from the embodiments of FIGS. 6 and 7 in that the light emitting elements LE are vertical type micro LED in which each of the plurality of light emitting elements LE extends in a third direction DR3. The vertical type micro LED refers to an LED having a structure in which a conductive layer E1, a first semiconductor layer SEM1, an active layer MQW, a second semiconductor layer SEM2, and a third semiconductor layer SEM3 are sequentially disposed along the third direction DR3, which is a vertical direction. Each of the plurality of light emitting elements LE may have a cross-sectional shape of a reverse taper. For example, in one or more embodiments, each of the plurality of light emitting elements LE may have a cross-sectional shape of a trapezoid in which the width of the top surface is wider than the width of the bottom surface. The shape of the light emitting elements LE may vary depending on the embodiments. For example, each of the plurality of light emitting elements LE may include a substantially vertical side surface. The light emitting element LE may be patterned through vertical etching and may have a rectangular or square cross-sectional shape in which the width of the top surface and the width of the bottom surface are substantially the same.

In the embodiment of FIG. 20 and FIG. 21, the description overlapping with the embodiment of FIG. 6 and FIG. 7 is omitted.

Referring to FIG. 20 and FIG. 21, a pixel electrode layer including pixel electrodes PXE1, PXE2, and PXE3 may be disposed on a second planarization organic film 180. The common electrode CE may be disposed on the top surface of each of the plurality of light emitting elements LE and the top surface of the third organic film 212. The common electrode CE may be a common layer formed commonly on the first sub-pixel SPX1, the second sub-pixel SPX2, and the third sub-pixel SPX3.

The pixel electrode layer may be disposed on the second planarization organic film 180. The pixel electrode layer may include a first pixel electrode PXE1, a second pixel electrode PXE2, and a third pixel electrode PXE3.

A first organic layer 210 may be disposed on each of the pixel electrodes PXE1, PXE2, and PXE3.

The plurality of light emitting elements LE may be disposed on the first organic layer 210.

Each of the plurality of light emitting elements LE may have a length in the first direction DR1, a length in the second direction DR2, and a length in the third direction DR3 of several to several hundred μm, respectively. For example, each of the plurality of light emitting elements LE may have a length in the first direction DR1, a length in the second direction DR2, and a length in the third direction DR3 of approximately 100 μm or less, respectively.

The light emitting element LE may include a conductive layer E1, a semiconductor stack STC, a contact electrode CTE, and a protective layer INS. The semiconductor stack STC may include a first semiconductor layer SEM1, an active layer MQW, a second semiconductor layer SEM2, and a third semiconductor layer SEM3 that are sequentially disposed along the third direction DR3.

The protective layer INS may be a film for protecting the light emitting element LE by being disposed on at least one side of the semiconductor stack STC and at least one side and the lower surface of the conductive layer E1. Specifically, the protective layer INS is disposed on the bottom surface and the side surface of the conductive layer E1, on the side surface of the first semiconductor layer SEM1, on the side surfaces of the active layer MQW, and on the side surfaces of the second semiconductor layer SEM2 and not on the side surfaces of the third semiconductor layer SEM3, but the present disclosure are not limited thereto. In one example, the protective layer INS may be disposed on the side surfaces of the first semiconductor layer SEM1 of the semiconductor stack STC, the side surfaces of the active layer MQW, and a portion of the side surface of the second semiconductor layer SEM2.

The protective layer INS may expose an area of the sidewall of the semiconductor stack STC that is adjacent to the top surface of the semiconductor stack STC without covering it. For example, the separation distance DS1 between the top surface of the semiconductor stack STC and the protective layer INS in the third direction DR3 may be greater than approximately 100 nm (e.g., see FIG. 7). Further, the separation distance DS1 between the top surface of the semiconductor stack STC and the protective layer INS in the third direction DR3 may be greater than the maximum length Lmax of the light extraction pattern LEP in the third direction DR3 (e.g., see FIG. 7). Here, the third direction DR3 may be substantially the same as the height direction (or thickness direction) of the light emitting element LE. In this way, when the protective layer INS is separated from the top surface of the semiconductor stack STC, the light emitting element LE may be easily separated from the base substrate on which the light emitting element LE is grown in the manufacturing process.

The protective layer INS may be formed from an inorganic film, for example, silicon nitride (SiNₓ), silicon oxide (SiON), silicon oxide (SiOₓ), titanium oxide (TiOₓ), and/or aluminum oxide (AlOₓ). In one or more embodiments, the insulating layer (INS) may be silicon oxide (SiOₓ).

The contact electrode CTE may be disposed on the protective layer INS. The contact electrode CTE may be disposed between the first organic layer 210 and the protective layer INS. The contact electrode CTE may be in contact with the first organic layer 210.

The contact electrode CTE may be connected to the exposed conductive layer E1 that is not covered by the protective layer INS.

The contact electrode CTE may include molybdenum (Mo), aluminum (Al), chromium (Cr), gold (Au), titanium (Ti), nickel (Ni), neodymium (Nd), and/or copper (Cu). Specifically, the contact electrode CTE may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The connection electrode BE (e.g., BE1, BE2) may be disposed between the contact electrode CTE and the first organic layer 210 and may extend along the first organic layer 210 onto the pixel electrode PXE1, PXE2, and PXE3. The connection electrode BE connects the contact electrode CTE of the light emitting element LE and one of the pixel electrodes PXE1, PXE2, and PXE3.

The common electrode CE may be disposed on a top surface of each of the plurality of light emitting elements LE and on a top surface of the third organic film 212. The common electrode CE may be a common layer formed commonly on the first sub-pixel SPX1, the second sub-pixel SPX2, and the third sub-pixel SPX3. The common electrode CE may be made of a transparent conductive material (TCO), such as indium tin oxide (ITO) and indium zinc oxide (IZO), which can transmit light.

The pixel electrodes PXE1, PXE2, and PXE3 may be referred to as an anode electrode or a first electrode, and the common electrode CE may be referred to as a cathode electrode or a second electrode.

The first capping layer CAP1 may be disposed on the common electrode CE.

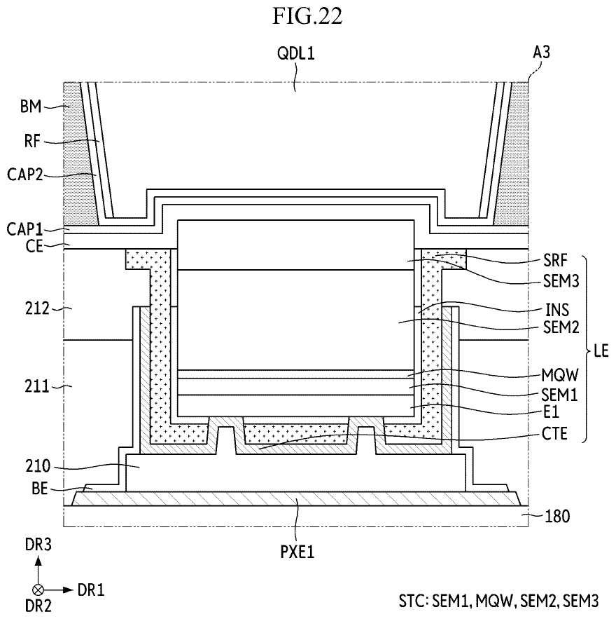

FIG. 22 is a cross-sectional view illustrating another example of the area A3 of FIG. 20 in detail.

The embodiment of FIG. 22 differs from the embodiment of FIG. 21 in that the light emitting element LE does not include a light extraction pattern LEP. In FIG. 22, descriptions that overlap with the embodiment of FIG. 21 will be omitted, and differences from the embodiment of FIG. 21 will be mainly described.

Referring to FIG. 22, the upper portion of the semiconductor stack STC does not include a light extraction pattern LEP. In the example of FIG. 22, the semiconductor stack STC includes, but is not limited to, a first semiconductor layer SEM1, an active layer MQW, a second semiconductor layer SEM2, and a third semiconductor layer SEM3. The semiconductor stack STC may include the first semiconductor layer SEM1, the active layer MQW, and the second semiconductor layer SEM2, and may not include the third semiconductor layer SEM3.

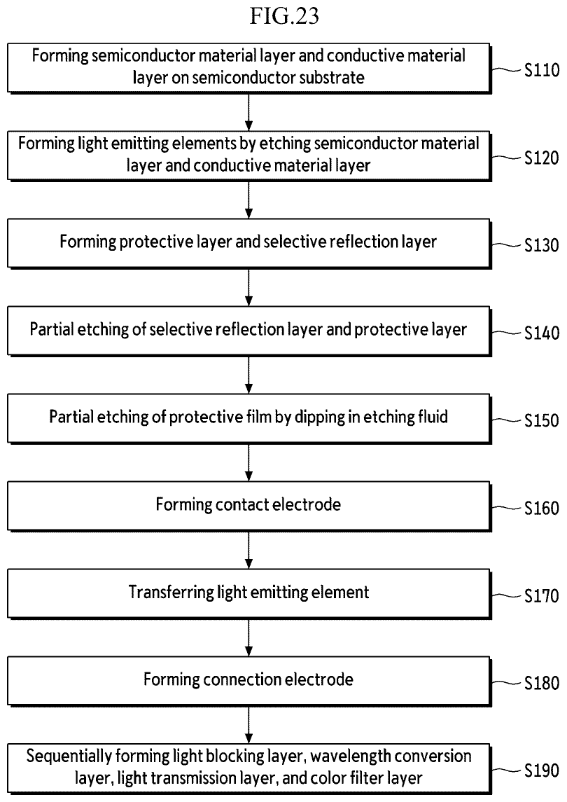

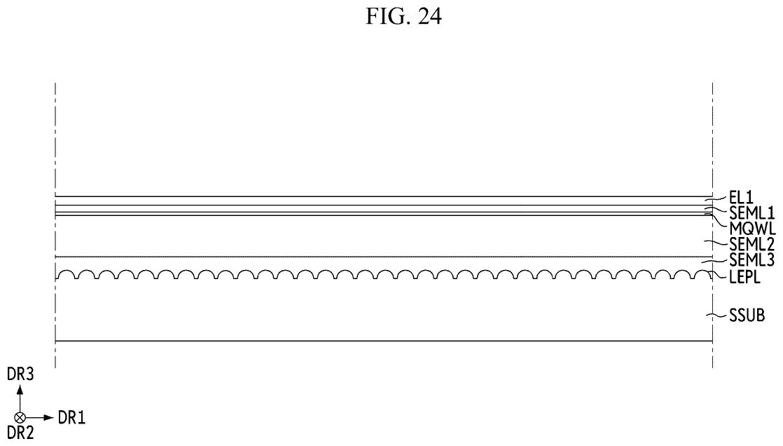

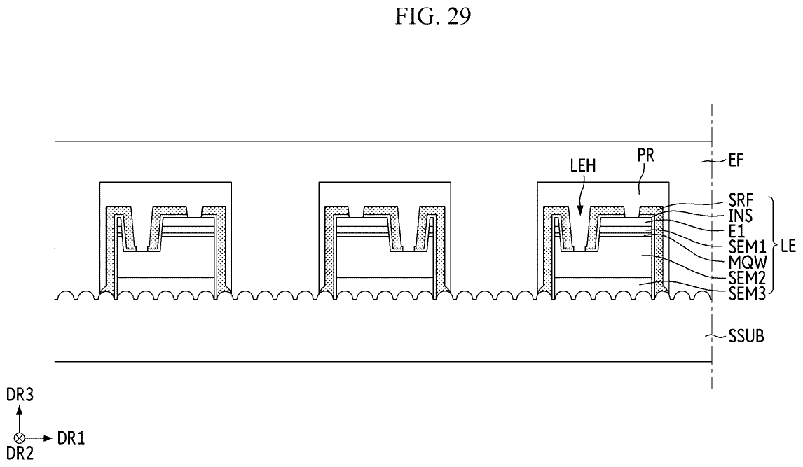

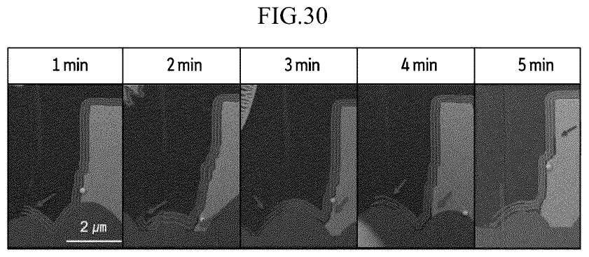

FIG. 23 is a flow chart illustrating a method for manufacturing a display device according to one or more embodiments. FIGS. 24-29 and FIGS. 31-36 are drawings to illustrate a method for manufacturing a display device according to one or more embodiments. FIG. 30 is an image to illustrate a protective layer and a selective reflection layer according to the dipping time of FIG. 29.

FIGS. 24-32 focus on the formation of the light emitting element.

Hereinafter, a method for manufacturing a display device illustrated in FIGS. 24-29 and FIGS. 31-36 will be described in connection with FIG. 23.

First, as shown in FIG. 24, a third semiconductor material layer SEML3, a second semiconductor material layer SEML2, an active material layer MQWL, a first semiconductor material layer SEML1, and a conductive material layer EL1 are formed on a semiconductor substrate SSUB. (S110 in FIG. 23)

The semiconductor substrate SSUB may be a silicon wafer substrate and/or a sapphire substrate. A light extraction pattern layer LEPL is formed on one surface of the semiconductor substrate SSUB. The light extraction pattern layer LEPL may include convex patterns formed into a hemisphere or a semi-ellipse. The light extraction pattern layer LEPL may include convex patterns having a cross-sectional shape of a semicircle or a semi-ellipse. The light extraction pattern layer LEPL may be formed of a semiconductor material layer, an organic film, and/or an inorganic film.

Then, a third semiconductor material layer SEML3 is formed on the light extraction pattern layer LEPL. Due to the light extraction pattern layer LEPL, light extraction patterns (LEP in FIG. 7) may be formed on one surface of the third semiconductor material layer SEML3.

The third semiconductor material layer SEML3 may be disposed to reduce the difference in lattice constant between the second semiconductor material layer SEML2 and the semiconductor substrate SSUB. In one example, the third semiconductor material layer SEML3 may include an undoped semiconductor and may be an undoped material of n-type or p-type. In one or more embodiments, the third semiconductor material layer SEML3 may be, but not limited to, undoped InAlGaN, GaN, AlGaN, InGaN, AlN, and/or InN.

A second semiconductor material layer SEML2 is formed on the third semiconductor material layer SEML3. The second semiconductor material layer SEML2 may be a semiconductor material layer doped with a second conductive dopant, such as silicon (Si), germanium (Ge), tin (Sn), and/or the like.

Then, an active material layer MQWL is formed on the second semiconductor material layer SEML2, and a first semiconductor material layer SEML1 is formed on the active material layer MQWL. The active material layer MQWL may include the same semiconductor material layer as the first semiconductor material layer SEML1 and the second semiconductor material layer SEML2. For example, when the first semiconductor material layer SEML1 and the second semiconductor material layer SEML2 include gallium nitride (GaN), the active material layer (MQWL) may also include gallium nitride (GaN). For example, the active material layer MQWL may include gallium nitride (GaN), indium gallium nitride (InGaN), and/or aluminum gallium nitride (AlGaN). The first semiconductor material layer SEML1 may be a semiconductor material layer doped with a first conductive dopant, such as magnesium (Mg), zinc (Zn), calcium (Ca), strontium (Sr), barium (Ba), and/or the like.

The light extraction pattern layer LEPL, the third semiconductor material layer SEML3, the second semiconductor material layer SEML2, the active material layer MQWL, and the first semiconductor material layer SEML1 may be formed on a semiconductor substrate SSUB through an epitaxial growth process. As an epitaxial growth process, a method of forming the light extraction pattern layer LEPL, the second semiconductor material layer SEML2, the active material layer MQWL, and the first semiconductor material layer SEML1 may be utilized electron beam deposition, physical vapor deposition (PVD), chemical vapor deposition (CVD), plasma laser deposition, (PLD), dual-type thermal evaporation, sputtering, metal organic chemical vapor deposition (MOCVD), and/or the like. Preferably, metal-organic chemical vapor deposition (MOCVD) may be utilized, but the present disclosure is not limited thereto.

Then, a conductive material layer EL1 is formed on the first semiconductor material layer SEML1. The conductive material layer EL1 may be formed of molybdenum (Mo), aluminum (Al), chromium (Cr), gold (Au), titanium (Ti), nickel (Ni), neodymium (Nd), and/or copper (Cu).

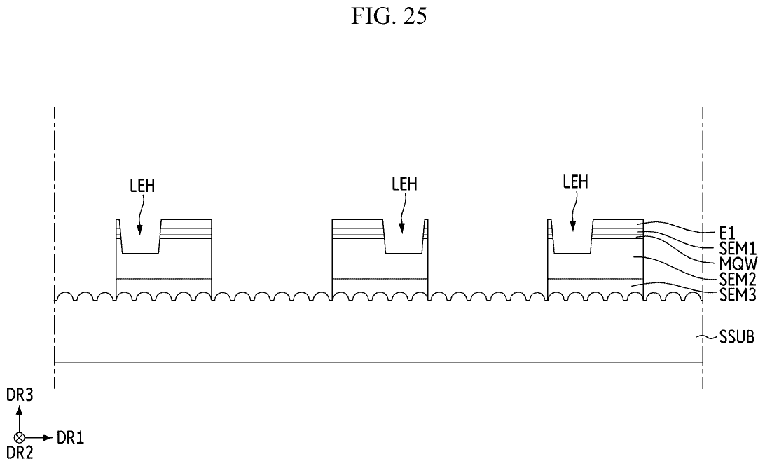

Second, as shown in FIG. 25, third semiconductor material layer SEML3, the second semiconductor material layer SEML2, the active material layer MQWL, the first semiconductor material layer SEML1, and the conductive material layer EL1 are etched to form light emitting elements LE. (S120 in FIG. 23)

After forming a mask pattern on the conductive material layer EL1, the third semiconductor material layer SEML3, the second semiconductor material layer SEML2, the active material layer MQWL, the first semiconductor material layer SEML1, and the conductive material layer EL1 are etched according to the mask pattern. The mask pattern may be removed after forming the light emitting elements LE.

The second semiconductor material layer SEML2, the active material layer MQWL, the first semiconductor material layer SEML1, and the conductive material layer EL1 may be etched by a dry etching method, a wet etching method, a reactive ion etching (RIE), a deep reactive ion etching (DRIE), an inductively coupled plasma reactive ion etching (ICP-RIE), etc. In the case of the dry etching method, anisotropic etching is possible and thus may be suitable for vertical etching. When the dry etching method is used, the etching gas may be chlorine (Cl₂) and/or oxygen (O₂) gas but is not limited to.

Then, a hole LEH is formed in each of the light emitting elements LE to expose the second semiconductor layer SEM2 by penetrating the conductive layer E1, the first semiconductor layer SEM1, and the active layer MQW.

Third, a protective layer INS and a selective reflection layer SRF having a first opening OP1 and a second opening OP2 may be formed on the entire surface of the semiconductor substrate SSUB. (S130 in FIG. 23)

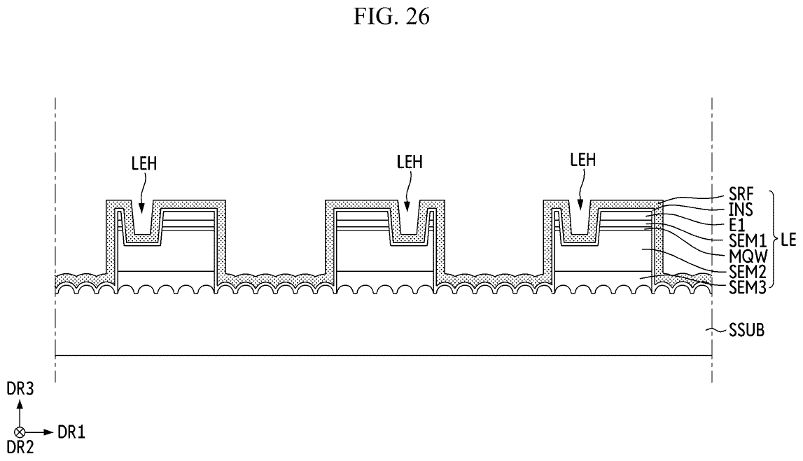

Referring to FIG. 26, the protective material layer INSL may be entirely deposited on one surface of the semiconductor substrate SSUB. The protective material layer INSL may be formed to cover one surface and side surfaces of the light emitting elements LE. The protective material layer INSL may be formed on one surface of the semiconductor substrate SSUB exposed between the light emitting elements LE.

Next, the selective reflection layer SRF may be entirely formed on one surface of the protective material layer INSL.

The selective reflection layer SRF may be formed by alternately depositing the first layer and the second layer on one side of the semiconductor substrate SSUB. The first layer may be etched by the same etching as the protective material layer INSL. The second layer may not be etched by the etching that etches the protective material layer INSL. For example, the protective material layer INSL and the first layer may be silicon oxide (SiOₓ). The second layer can be titanium oxide (TiOₓ). The etching may be a silicon oxide film etching, such as a buffered oxide etch (BOE).

A portion of the protective layer INS and the selective reflection layer SRF are etched to expose a portion of the conductive layer E1 and a portion of the second semiconductor layer SEM2.

To this end, a first mask pattern is formed on the selective reflection layer SRF.

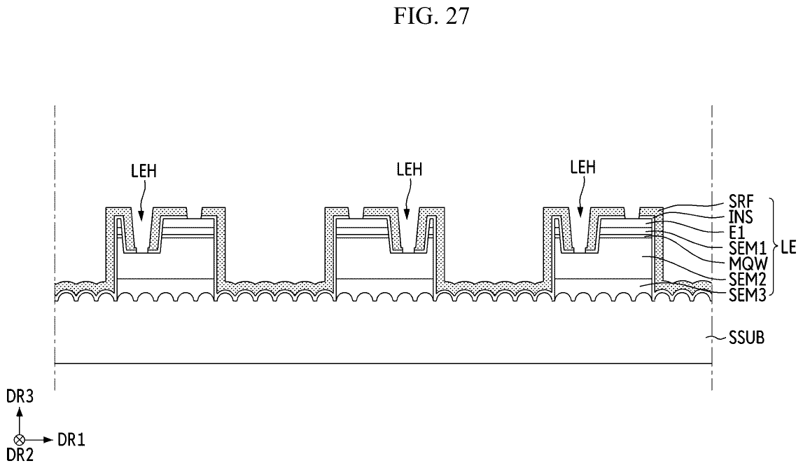

Referring to FIG. 27, the first mask pattern may be formed to expose a portion of the hole LEH of each of the light emitting elements LE. For example, the first mask pattern may form a first opening OP1 by etching a portion of the selective reflection layer SRF and the protective layer INS disposed on one surface of each of the light emitting elements LE. Further, the first mask pattern may form a second opening OP2 so as not to cover the selective reflection layer SRF and the protective layer INS disposed on the bottom surface of the hole LEH of each of the light emitting elements LE. The conductive layer E1 may be exposed by the first opening OP1, and the second semiconductor layer SEM2 may be exposed by the second opening OP2 (e.g., see FIG. 7).

Fourth, the selective reflection layer SRF and the protective layer INS that do not overlap the light emitting element LE are etched. (S140 in FIG. 23)

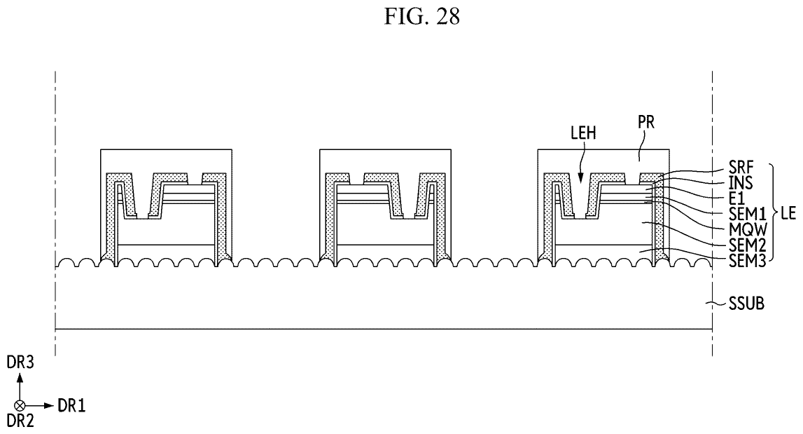

Referring to FIG. 28, a photoresist pattern PR covering the light emitting element LE is formed. The photoresist pattern PR may protect the light emitting element LE during the etching process. After that, a part of the selective reflection layer SRF and the protective layer INS may be etched using a photo process. The photo process is a process for forming a desired structure by passing light through a mask formed according to a desired pattern after applying photoresist PR on a substrate. As such, a photo process tolerance may occur due to the mask and the passage of light in the photo process. For example, the photoresist PR may be formed to surround the light emitting element LE. The selective reflection layer SRF and the protective layer INS may be etched using the photoresist PR as a mask. In this way, when photoresist PR is used as a mask, a portion protruding outward from the bottom of the semiconductor stack occurs due to the photo process tolerance. The photo process tolerance may vary depending on the photo equipment but may be approximately 0.5 μm to 2 μm. Therefore, the protruding length of the selective reflection layer SRF and the protective layer INS may be formed within a range of 0.6 μm to 2.4 μm including approximately 20% margin in the photo process tolerance.

Fifth, a portion of the protective layer INS is etched by dipping in an etching fluid EF. (S150 in FIG. 23)

For example, referring to FIG. 29, the etching fluid EF may react to the silicon oxide (SiOₓ) forming the protective layer INS and may not react to the titanium oxide (TiOₓ) forming the second layer of the selective reflection layer SRF.

Referring to FIG. 30, the length of the protective layer INS decreases as the dipping time increases. Along with the length of the protective layer INS, the length of the first layers of the selective reflection layer SRF also changes.

For example, after three minutes, the protective layer INS that does not overlap with the light emitting element LE is completely etched, and the first layers of the selective reflection layer SRF are shorter than the second layers of each pair. After five minutes, the protective layer INS is etched and removed up to the side of the light emitting element LE. At this time, if the time is too long, the protective layer INS on the side of the active layer MQW may be removed, so the time may be adjusted well. In addition, the first layers of the selective reflection layer SRF are also removed from the portion that does not overlap with the light emitting element LE. The etching time may vary depending on the concentration of the etching, the thickness of the protective layer INS and the selective reflection layer SRF, etc.

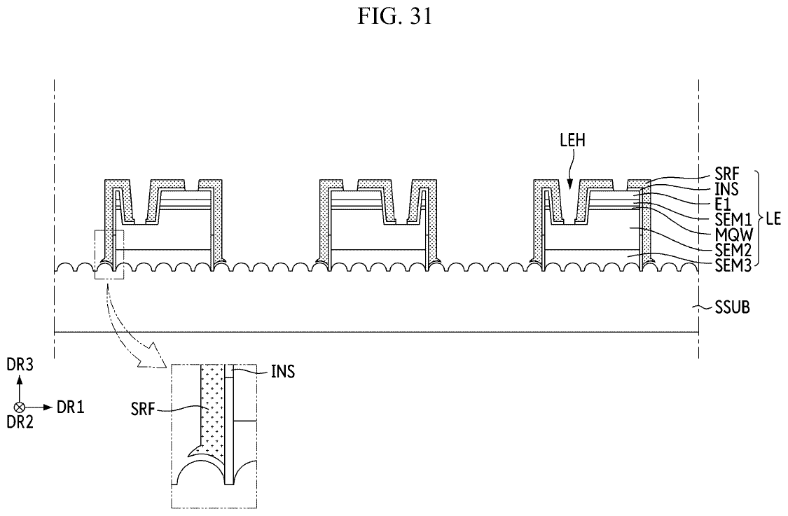

As shown in FIG. 31, when the non-overlapping protective layer INS with the light emitting element LE is etched, the light emitting element LE may be easily separated from the semiconductor substrate SSUB in a subsequent transfer process. Here, easy separation means that, for example, when the light emitting element LE is separated from the semiconductor substrate SSUB by laser irradiation, the semiconductor substrate SSUB may be separated even with relatively low laser power. If the separation is not easy in the separation process between the light emitting element LE and the semiconductor substrate SSUB and a high laser power is required, the dispersion of the current-voltage curve of the light emitting element LE increases and delayed lighting may occur. Furthermore, the problem of the protective layer of the light emitting element LE being peeled off may also occur. Conversely, as in one or more embodiments, if the protective layer INS that does not overlap the light emitting element LE is etched to separate the protective layer INS and the semiconductor substrate SSUB, the light emitting element LE may be easily separated from the semiconductor substrate SSUB with relatively low laser power when transferring the light emitting element LE to the target substrate.

After the dipping process is completed, the photoresist (PR) can be removed by an ashing process.

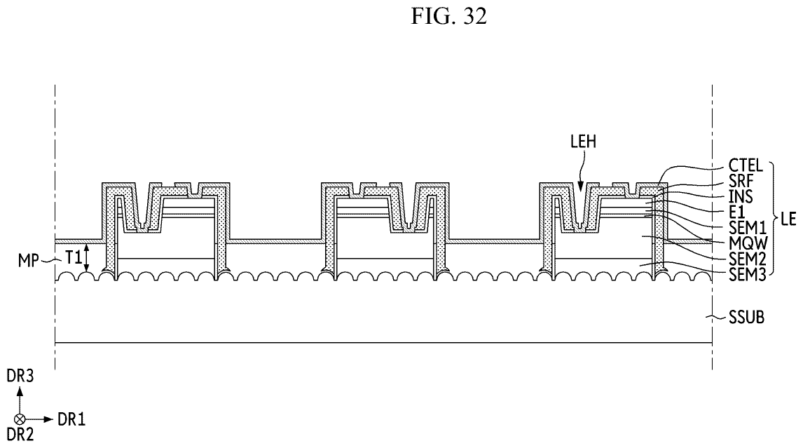

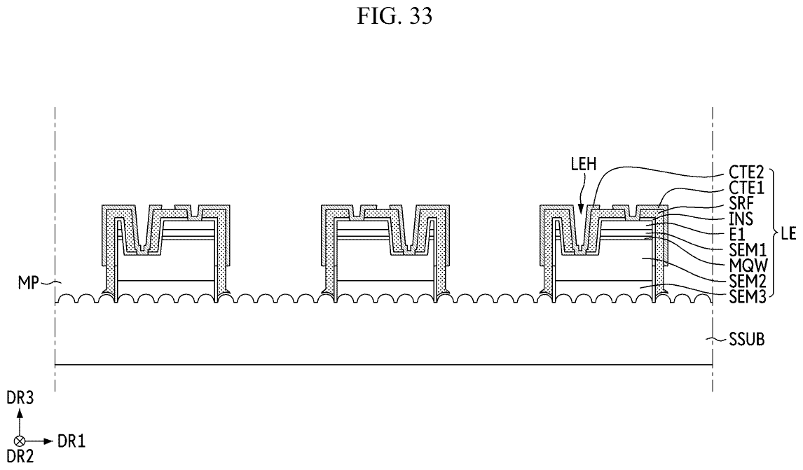

Sixth, as shown in FIGS. 32 and 33, contact electrodes CTE1 and CTE2 are formed. (S160 in FIG. 23)

The mask pattern MP may be formed with a first thickness T1 between the light emitting elements LE as shown in FIG. 32.

Then, a contact electrode layer CTEL is completely deposited on one surface of the semiconductor substrate SSUB to cover the light emitting element LE and the mask pattern MP. The contact electrode layer CTEL may be formed on one side of the semiconductor substrate SSUB exposed between the light emitting elements LE.

The mask pattern MP is removed by a lift-off process, and first contact electrodes CTE1 and second contact electrodes CTE2 are formed.

The mask pattern MP may be formed with a negative photoresist to remove the mask pattern MP by a lift-off process. In this case, the mask pattern MP and the contact electrode layer CTE disposed on the mask pattern MP may be removed by a solvent ashing process using alcohol.

When the mask pattern MP is removed, the first contact electrode CTE1 connected to the conductive layer E1 and the second contact electrode CTE2 connected to the second semiconductor layer SEM2 are disposed separately, and thus may be electrically isolated from each other. Furthermore, the first contact electrode CTE1 and the second contact electrode CTE2 may be exposed without covering the protective layer INS disposed on the side surface of the third semiconductor layer SEM3.

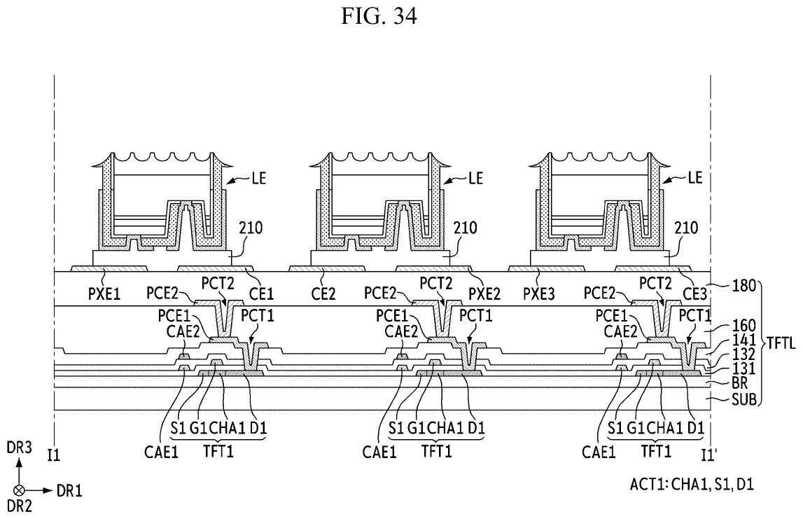

Seventh, as shown in FIG. 34, the light emitting elements LE are transferred to the first organic film 210 disposed on the pixel electrodes PXE1, PXE2, PXE3, and the common electrodes CE1, CE2, CE3, and the semiconductor substrate SSUB is removed. (S170 in FIG. 23)

The light emitting elements LE may be transferred onto the first organic layer 210 disposed on the pixel electrodes PXE. At this time, the light emitting elements LE may be temporarily fixed by being embedded in the first organic layer 210. In FIG. 34, the first contact electrode CTE1 and the second contact electrode CTE2 of each of the light emitting elements LE are shown as an example as being disposed on the first organic layer 210, but the present disclosure is not limited thereto. For example, the first organic layer 210 may be disposed on a portion of the bottom surface and side surface of the first contact electrode CTE1 of each of the light emitting elements LE and a portion of the bottom surface and side surface of the second contact electrode CTE2. Alternatively, the first organic layer 210 may be disposed on the side surfaces of the conductive layer E1 of each of the light emitting elements LE. Alternatively, the first organic layer 210 may be disposed on the side surfaces of the first semiconductor layer SEM1, the side surfaces of the active layer MQW, and the side surfaces of the second semiconductor layer SEM2 of each of the light emitting elements LE. In this case, the first organic layer 210 may be disposed on a portion of each of the side surfaces of the second semiconductor layer SEM2.

When the fluidity of the first organic layer 210 is small or the first organic layer 210 is solid, the depth at which the light emitting element LE is inserted or embedded in the first organic layer 210 is very small, or the light emitting element LE may be disposed on the first organic layer 210 without being inserted or embedded in the first organic layer 210.

When the first organic layer 210 is a photosensitive organic film such as a photoresist, the first organic layer 210 may be soft baked at a first temperature, and then at least a portion of each of the plurality of light emitting elements LE is inserted into the first organic layer 210. Then, the first organic layer 210 may be completely hardened at a second temperature higher than the first temperature. The first temperature may be approximately 100 degrees Celsius, and the second temperature may be approximately 230 degrees Celsius, but the present disclosure is not limited thereto. Furthermore, the process of completely curing the first organic layer 210 at the second temperature may be performed for approximately 30 minutes.

Then, the semiconductor substrate SSUB is removed by the laser lift-off process. Alternatively, if the light emitting elements LE are transferred to a separate transfer substrate instead of the semiconductor substrate SSUB, the transfer substrate may be removed instead of the semiconductor substrate SSUB.

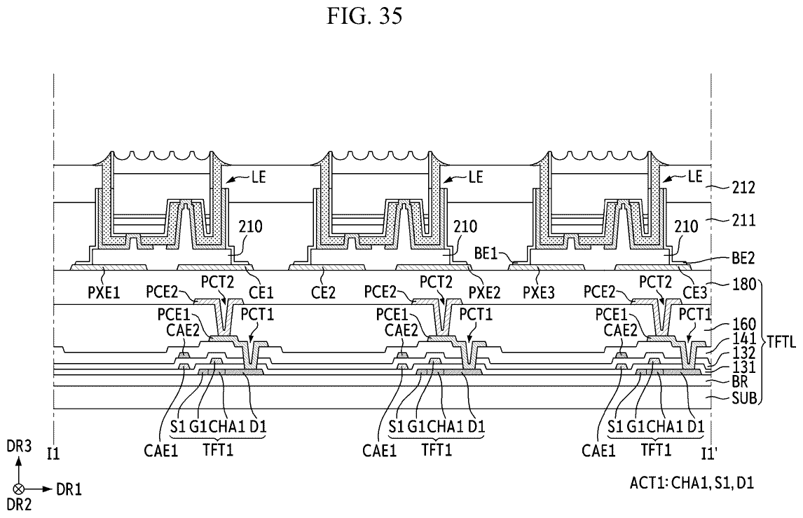

Eighth, as in FIG. 35, first connection electrodes BE1 and second connection electrodes BE2 are formed, and a second organic film 211 and a third organic film 212 are formed. (S180 in FIG. 23)

The first connection electrodes BE1 for connecting the first contact electrode CTE1 and the pixel electrodes PXE1, PXE2, PXE3, of the light emitting element LE disposed on the first organic film 210, and the second connection electrodes BE2 for connecting the second contact electrode CTE2 and the common electrodes CE1, CE2, CE3 are formed.

Then, the light emitting elements LE are fixed, and the second organic film 211 and the third organic film 212 are formed for flattening the steps caused by the light emitting elements LE.

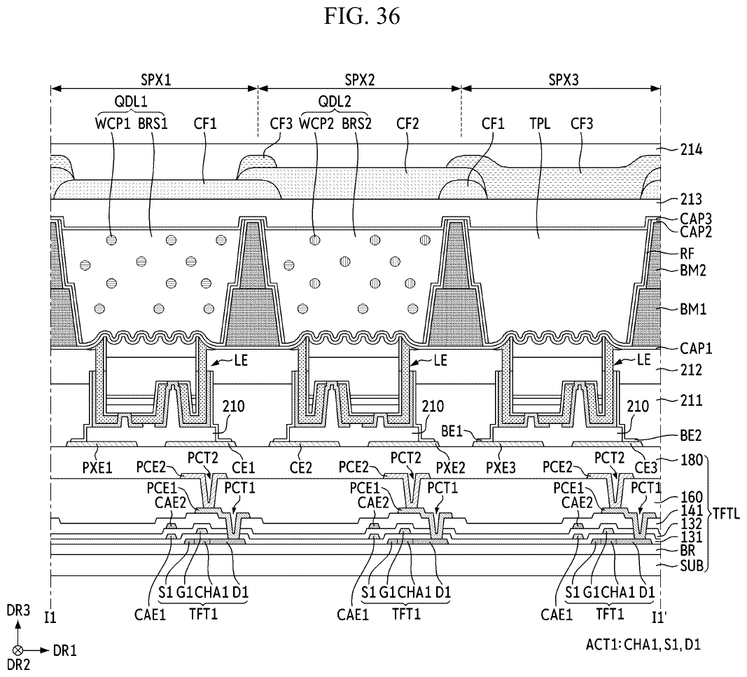

Ninth, as shown in FIG. 36, a light blocking layer, a wavelength conversion layer, a light transmission layer, and a color filter layer are sequentially formed. (S190 in FIG. 23)

A first capping layer CPL1 is formed on the third organic film 212 and the light emitting elements LE, and a first light blocking layer BM1 and a second light blocking layer BM2 are formed on the first capping layer CPL1 so as not to overlap with the light emitting elements LE in the third direction DR. Then, a second capping layer CPL2 covering the first light blocking layer BM1, the second light blocking layer BM2, and the first capping layer CPL1 is formed. Then, a reflective film RF covering the second capping layer CPL2 disposed on the first light blocking layer BM1 and the second light blocking layer BM2 is formed.

Then, a first light conversion layer QDL1 is formed on each of the first sub-pixels SPX1, a second light conversion layer QDL2 is formed on each of the second sub-pixels SPX2, and a light transmission layer TPL is formed on each of the third sub-pixels SPX3. Then, a third capping layer CPL3 is formed covering the first light conversion layer QDL1, the second light conversion layer QDL2, and the light transmission layer TPL.

Then, a fourth organic film 213 is formed on the third capping layer CPL3, a first color filter CF1 is formed that overlaps the first light conversion layer QDL1 in the third direction DR3, a second color filter CF2 is formed that overlaps the second light conversion layer QDL2 in the third direction DR3, and a third color filter CF3 is formed that overlaps the light transmission layer TPL in the third direction DR3 on the fourth organic film 213. The first color filter CF1, the second color filter CF2, and the third color filter CF3 may all be formed in the region overlapping the first light blocking layer BM1 and the second light blocking layer BM2 in the third direction DR3.

Then, a fifth organic film 214 is formed on the first color filter CF1, the second color filter CF2, and the third color filter CF3.

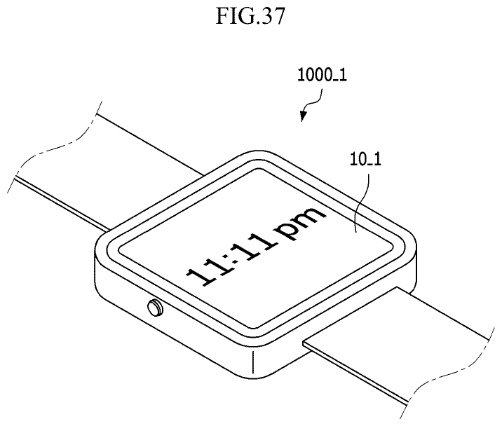

FIG. 37 is an example view of a smart watch including a display device according to one or more embodiments.

Referring to FIG. 37, a display device 10_1 according to one or more embodiments may be applied to a smart watch 1000_1 which is one of smart devices.

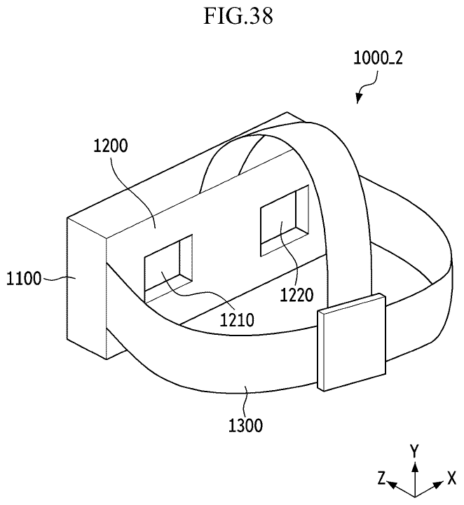

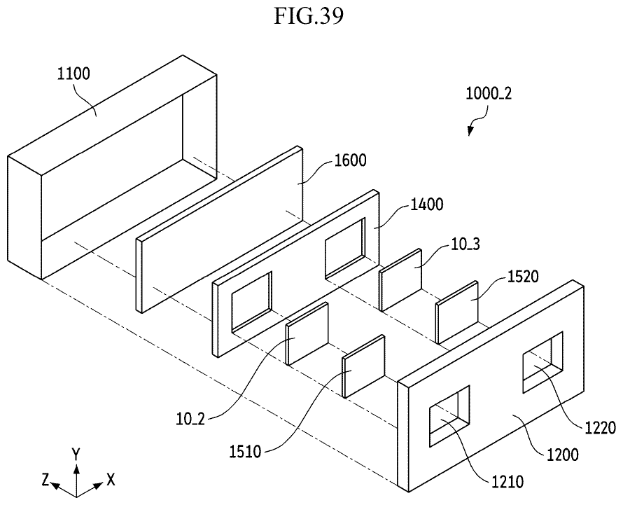

FIGS. 38 and 39 are example views of a virtual reality (VR) device including a display device according to one or more embodiments.

Referring to FIGS. 38 and 39, a head mounted display device 1000_2 according to one or more embodiments includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 103 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and may be disposed between the second display device 10_3 and the control circuit board 1600. The middle frame 1400 supports and fixes the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user's left eye to the first display device 10_2 and transmit the digital video data DATA corresponding to a right image optimized for the user's right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 38 and 39, the present disclosure is not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

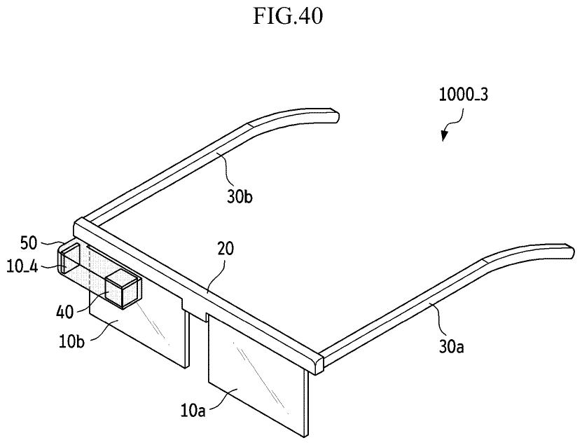

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head mounted display device 1000_2 may include an eyeglass frame as illustrated in FIG. 40 instead of the head mounted band 1300.

In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 40 is an example view of a VR device including a display device according to one or more embodiments. FIG. 40 illustrates a VR device 1000_3 to which a display device 10_4 according to one or more embodiments has been applied.

Referring to FIG. 40, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 40, a case where the VR device 1000_3 is a glasses-type display device including the eyeglass frame legs 30a and 30b is illustrated as an example. That is, the VR device 1000_3 according to the embodiment is not limited to the one illustrated in FIG. 40 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 40, the present disclosure is not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

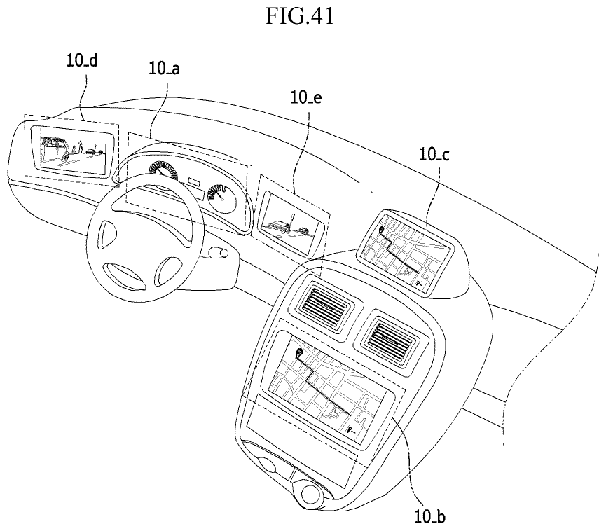

FIG. 41 is an example view illustrating a vehicle instrument cluster and center fascia including display devices according to one or more embodiments. FIG. 41 illustrates a vehicle to which display devices 10_a through 10_e according to one or more embodiments have been applied.

Referring to FIG. 41, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

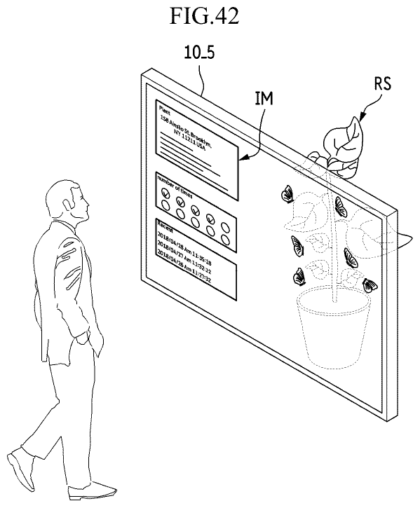

FIG. 42 is an example view of a transparent display device including a display device according to one or more embodiments.

Referring to FIG. 42, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A light emitting element comprising:
a semiconductor stack comprising a first semiconductor layer, an active layer, and a second semiconductor layer;
a conductive layer on a first surface of the semiconductor stack;
a protective layer on side surfaces of the conductive layer, a side surface of the semiconductor stack, and the first surface of the conductive layer, and spaced from a second surface facing the first surface of the semiconductor stack;
a contact electrode on one surface of the semiconductor stack;
a selective reflection layer on the side surfaces of the conductive layer, the side surface of the semiconductor stack, and the first surface of the conductive layer outside the protective layer, and including an opening overlapping the contact electrode,
wherein the selective reflection layer comprises M pairs of first and second layers (M is an integer greater than or equal to 2), wherein the first layer of each pair is closer to the semiconductor stack than the second layer, and wherein a length of the first layer in each pair is different from a length of the second layer.

2. The light emitting element of claim 1, wherein lengths of the first layers in different pairs of the semiconductor stack are different.

3. The light emitting element of claim 1, wherein lengths of the first layers in different pairs decrease as distance from the light emitting element of the first layers in different pairs decrease.

4. The light emitting element of claim 1, wherein a refractive index of the first layer is lower than a refractive index of the second layer.

5. The light emitting element of claim 1, wherein the semiconductor stack further comprises a third semiconductor layer on the second semiconductor layer.

6. The light emitting element of claim 1, wherein the semiconductor stack further comprises light extraction patterns in a concave cross-sectional shape on a top surface of the semiconductor stack.

7. The light emitting element of claim 6, wherein the protective layer covers a side surface of the active layer, and
wherein a distance between the top surface of the semiconductor stack and the protective layer in a height direction of the light emitting element is greater than a maximum length of one of the light extraction patterns in the height direction of the light emitting element.

8. The light emitting element of claim 1, wherein the protective layer and the first layer comprise silicon oxide, and wherein the second layer comprises titanium oxide.

9. The light emitting element of claim 1, wherein the contact electrode comprises a first contact electrode connected to the conductive layer exposed without being covered by the protective layer, and a second contact electrode connected to the second semiconductor layer exposed without being covered by the protective layer and the selective reflection layer.

10. The light emitting element of claim 9, wherein the second contact electrode is in a hole penetrating the conductive layer and a portion of the semiconductor stack.

11. The light emitting element of claim 1, wherein the contact electrode is connected to the conductive layer that is exposed and not covered by the protective layer.

12. A display device comprising:
a substrate;
a pixel electrode layer on the substrate;
a light emitting element on the pixel electrode layer,
wherein the light emitting element comprises:
a semiconductor stack comprising a first semiconductor layer, an active layer, and a second semiconductor layer;
a conductive layer on a first surface of the semiconductor stack;
a protective layer on side surfaces of the conductive layer, a side surface of the semiconductor stack, and a first surface of the conductive layer, and spaced from a second surface opposing the first surface of the semiconductor stack;
a contact electrode on one surface of the semiconductor stack; and
a selective reflection layer on the side surfaces of the conductive layer, the side surface of the semiconductor stack, and the first surface of the conductive layer outside the protective layer, and including an opening overlapping the contact electrode,
wherein the selective reflection layer includes M (M is an integer greater than or equal to 2) pairs of first and second layers, wherein the first layer of each pair is closer to the semiconductor stack than the second layer, and wherein a length of the first layer in each pair is different from a length of the second layer.

13. The display device of claim 12,
wherein the pixel electrode layer comprises a pixel electrode and a common electrode that is spaced from the pixel electrode, and
wherein the contact electrode comprises a first contact electrode connected to the conductive layer exposed without being covered by the protective layer, and a second contact electrode connected to the second semiconductor layer exposed without being covered by the protective layer and the selective reflection layer.

14. The display device of claim 13, further comprises
an organic film on a portion of the pixel electrode and the common electrode;
a first connection electrode connecting the first contact electrode and the pixel electrode; and
a second connection electrode connecting the second contact electrode and the common electrode.

15. The display device of claim 12,
wherein the pixel electrode layer comprises a pixel electrode,
wherein the contact electrode is connected to the conductive layer that is exposed and not covered by the protective layer, and
wherein the display device further comprises a common electrode on the light emitting element.

16. The display device of claim 15, further comprises:
an organic film on the pixel electrode;
a connection electrode connecting the contact electrode and the pixel electrode.

17. An electronic device comprising:
a display device for displaying an image, wherein the display device comprises:
a substrate;
a pixel electrode layer on the substrate;
a light emitting element on the pixel electrode layer,
wherein the light emitting element comprises:
a semiconductor stack comprising a first semiconductor layer, an active layer, and a second semiconductor layer;
a conductive layer on a first surface of the semiconductor stack;
a protective layer on side surfaces of the conductive layer, a side surface of the semiconductor stack, and a first surface of the conductive layer, and spaced from a second surface opposing the first surface of the semiconductor stack;
a contact electrode on one surface of the semiconductor stack; and
a selective reflection layer on the side surfaces of the conductive layer, the side surface of the semiconductor stack, and the first surface of the conductive layer outside the protective layer, and including an opening overlapping the contact electrode,
wherein the selective reflection layer comprises M (M is an integer greater than or equal to 2) pairs of first and second layers, wherein the first layer of each pair being closer to the semiconductor stack than the second layer, and wherein a length of the first layer in each pair is different from a length of the second layer.

18. The electronic device of claim 17,
wherein the pixel electrode layer comprises a pixel electrode and a common electrode that is spaced from the pixel electrode, and
wherein the contact electrode comprises a first contact electrode connected to the conductive layer exposed without being covered by the protective layer, and a second contact electrode connected to the second semiconductor layer exposed without being covered by the protective layer and the selective reflection layer.

19. The electronic device of claim 18, further comprises
an organic film on a portion of the pixel electrode and the common electrode;
a first connection electrode connecting the first contact electrode and the pixel electrode; and
a second connection electrode connecting the second contact electrode and the common electrode.

20. The electronic device of claim 17,
wherein the pixel electrode layer comprises a pixel electrode,
wherein the contact electrode is connected to the conductive layer that is exposed and not covered by the protective layer, and
wherein the display device further comprises a common electrode on the light emitting element.
